(19) United States
(12) Patent Application Publication
(10) Pub. No.: US 2011/0227087 A1
(43) Pub. Date: Sep. 22, 2011

(54) SUBSTRATE FOR DISPLAY DEVICE, AND DISPLAY DEVICE

(75) Inventors: Hiroyuki Moriwaki, Osaka (JP); Kouhei Tanaka, Osaka (JP); Hiroyuki Ogawa, Osaka (JP)

(73) Assignee: SHARP KABUSHIKI KAISHA, Osaka (JP)

(21) Appl. No.: 13/130,552

(22) PCT Filed: Nov. 19, 2009
(86) PCT No.: PCT/JP2009/069632

§ 371 Date: May 20, 2011

(30) Foreign Application Priority Data
Nov. 28, 2008 (JP) 2008-305300

(51) Int. Cl. H01L 27/06

(52) U.S. Cl. 257/71; 257/E27.016

(57) ABSTRACT

Disclosed is a display device substrate and a display device in which a peripheral circuit is provided in a frame region that can achieve a higher aperture ratio while suppressing the production cost. The display device substrate includes a peripheral circuit provided in a frame region, a first pixel auxiliary capacitance, and a thin film transistor. The first pixel auxiliary capacitance includes an upper electrode and a lower electrode. The peripheral circuit includes wirings. The thin film transistor includes a gate electrode. The upper electrode and the lower electrode are disposed above the gate electrode, and formed of the same material as the wirings.

### TECHNICAL FIELD

The present invention relates to a display device substrate and a display device. More particularly, the present invention relates to a display device substrate in which a peripheral circuit is provided in the frame region, a display device suitable for a display device, and to a display device.

### BACKGROUND ART

In the pixel section of the display devices such as liquid crystal display devices and organic EL displays, providing a pixel auxiliary capacitance is an important means to obtain a display device having a higher display quality. That is, the larger the pixel auxiliary capacitance is, the higher the display quality becomes. However, if a pixel auxiliary capacitance is provided in a pixel, the occupancy of the pixel auxiliary capacitance in the pixel reduces the pixel aperture ratio. Conventionally, a larger pixel auxiliary capacitance lowered the pixel aperture ratio, and a smaller pixel auxiliary capacitance lowered the display quality. That is, there was a trade-off relationship between the pixel aperture ratio and the display quality.

On the other hand, for active matrix display devices, technologies have been disclosed in which an auxiliary capacitance (black matrix in contact with an inorganic layer/inorganic layer/pixel electrode in contact with the inorganic layer) is formed on an interlayer insulating film made of an organic resin film (see Patent Document 1, for example).

Also, a liquid crystal display device is disclosed in which the auxiliary capacitance is formed of: a pixel electrode; a transparent insulating film for auxiliary capacitance formed at least below the pixel electrode; and a common electrode made of a transparent conductive film disposed below the transparent insulating film for auxiliary capacitance and connected to a particular potential, while the thicknesses of the pixel electrode, the transparent insulating film for auxiliary capacitance, and the common electrode are such that their transmittance for the light having a particular wavelength increases due to an interference (see Patent Document 2, for example).

Furthermore, an active matrix type display device is disclosed in which a common electrode is disposed between the pixel electrode layer and the source wiring and gate wiring layers, and the common electrode is made of a material that blocks the visible light by covering the source wiring and the gate wiring, the peripheral area of the pixel electrode overlaps the common electrode, and the common electrode is connected to a wiring in the same layer as the source wiring via a film that is in the same layer as the pixel electrode (see Patent Document 3, for example).

These technologies are devised focusing on the pixel structure, and are based on the use of some of the constituent elements of pixels to improve the pixel aperture ratio.

Recently, in an attempt to further narrow the screen frame, efforts were made to improve the integration level of peripheral circuits provided in the frame region of a display device. For this purpose, development is underway of a multi-layer wiring technology used in substrates for semiconductor devices such as semiconductor substrates, for application to display device substrates such as glass substrates.

Functional screens such as liquid crystal sensor screens in which an optical sensor is formed within the pixel are also being developed.

### RELATED ART DOCUMENTS

### Patent Documents

Patent Document 1: Japanese Patent Application Laid-Open Publication No. H11-249171
Patent Document 2: Japanese Patent Application Laid-Open Publication No. 2001-33818
Patent Document 3: Japanese Patent Application Laid-Open Publication No. H10-10581

### SUMMARY OF THE INVENTION

### Problems to be Solved by the Invention

However, according to the technologies disclosed in Patent Documents 1 and 3, because a black mask is formed to cover the source wiring and the auxiliary capacitance wiring, the aperture ratio is lowered compared to the case in which the pixel is formed of the source wiring and the auxiliary capacitance wiring alone. Also, since the black mask used could be replaced by the source wiring or the auxiliary capacitance wiring, the production cost is actually increased. Furthermore, in the technology disclosed in Patent Document 1, the black mask needs to be formed larger than the wiring below the source wiring or the auxiliary capacitance wiring.

Also, according to the technology disclosed in Patent Document 2, an additional transparent insulating film for auxiliary capacitance and a common electrode need to be formed, which drives up the production cost.

Furthermore, in the processes using the multi-layer wiring technology, increased number of manufacturing steps are required, indicating that such processes are inherently expensive. Therefore, production costs further increase if any of the technologies disclosed in Patent Documents 1 to 3 is applied to a display device substrate having multi-layer wirings.

As discussed above, for display device substrates having multi-layer wirings, using to the full advantage of the multi-layer wiring is sought while curbing costs and providing added values.

For functional screens where optical sensors are provided in pixels, an optical sensor circuit needs to be formed in a pixel, and that tends to lower the pixel aperture ratio. Therefore, functional screens also have room for improvement in that a higher pixel aperture ratio should be achieved.

The present invention was devised in consideration of the current situation as described above, and is aiming at providing a display device substrate and a display device that has peripheral circuits in the frame region, and is capable of achieving a high aperture ratio while curbing the production cost.

### Means for Solving the Problems

The inventors of the present invention researched for a display device substrate and display device that have peripheral circuits in the frame region and is capable of achieving a high aperture ratio while curbing the production cost. Subsequently, the inventors focused on the wirings included in the peripheral circuit, and found that by using electrodes, which are disposed above the gate electrode of the thin film transistor and are made of the same material as the wirings included in the peripheral circuit, as the upper and lower electrodes that constitute the pixel auxiliary capacitance, a display device substrate having a multi-layer wirings becomes capable of achieving a high aperture ratio while curving the production cost. As a result, the above-mentioned problems have been admirably solved, leading to completion of the present invention.

That is, the present invention is a display device substrate including a peripheral circuit provided in a frame region, a first pixel auxiliary capacitance, and a thin film transistor, wherein the first pixel auxiliary capacitance includes an upper electrode and a lower electrode, the peripheral circuit includes wirings, the thin film transistor includes a gate electrode, and the upper electrode and the lower electrode are disposed above the gate electrode and are formed of same materials the wirings.

Accordingly, during manufacturing processes in which wirings included in a peripheral circuit are formed, the upper electrode and the lower electrode constituting the first pixel auxiliary capacitance can be formed simultaneously, respectively. Because a wiring, a transistor, an optical sensor circuit and the like can also be made below the first pixel auxiliary capacitance, both an increase in the first pixel auxiliary capacitance and the aperture ratio improvement can be achieved. As a result, a display device substrate that has a peripheral circuit provided in the frame region and is capable of achieving a high aperture ratio while curbing the production cost can be obtained. Also, an optical sensor circuit and a second pixel auxiliary capacitance can be disposed below the first pixel auxiliary capacitance. This makes it possible to provide added value to a display device while maintaining a high aperture ratio. Furthermore, by utilizing the multi-layer wiring technology in which a dry process is used, a display device substrate of the present invention can be manufactured without requiring any additional manufacturing step. When the multi-layer wiring technology using a wet process is utilized, part of the manufacturing costs of the display device substrate can be eliminated.

Here, the term “same” means exactly the same preferably, but it may mean similar enough to be formed in the same formation processes. That is, the upper electrode and the lower electrode may be formed of substantially the same materials as those of which the wirings are formed, or may be formed in the same manufacturing steps in which the wirings are formed.

The configuration of a display device substrate of the present invention is not specifically limited, and as long as these constituent elements are included as essential components of the configuration, other constituent elements may, but does not need to, be included.

Preferred embodiments of a display device substrate of the present invention are described in detail below. The embodiments described below may be combined as appropriate.

From the perspective of effectively suppressing the reduction in coverage of the insulating film of the first pixel auxiliary capacitance, outside the region where the first pixel auxiliary capacitance is formed, the lower electrode is preferably connected to a conductive layer through a first contact hole provided in the insulating film of lower layer. Accordingly, outside the region where the first pixel auxiliary capacitance is formed, the lower electrode may be connected to a conductive layer of a lower layer through a contact hole. The conductive layer is not particularly limited, as long as it is a member that can be connected to the lower electrode of the first pixel auxiliary capacitance. The conductive layer can be, for example, an electrode, a wiring, or a high-concentration impurity region of a semiconductor.

In this specification, “contact hole” may also be a so-called through hole (via hole).

The display device substrate may have a second pixel auxiliary capacitance below the first pixel auxiliary capacitance. As a result, compared to the case where only one pixel auxiliary capacitance is included in a pixel, the sizes (areas) of the first pixel auxiliary capacitance and the second pixel auxiliary capacitance can be reduced.

The second pixel auxiliary capacitance includes an upper electrode and a lower electrode, and preferably the lower electrode of the first pixel auxiliary capacitance does not extend beyond the upper electrode of the second pixel auxiliary capacitance when the display device substrate is observed in a plan view. As a result, even when a conventional, common PECVD device, which has issues regarding flatness, is used to form a TEOS film or a SiN film, which is used as an interlayer insulating film interposed between the first pixel auxiliary capacitance and the second pixel auxiliary capacitance, the insulation breakdown across the first pixel auxiliary capacitance can be suppressed from occurring.

From the perspective of suppressing defect occurrences, such as insulation breakdowns, from occurring in the first pixel auxiliary capacitance and the second pixel auxiliary capacitance, preferably the display device substrate has a first auxiliary capacitance wiring and a second auxiliary capacitance wiring that is different from the first auxiliary capacitance wiring, the first pixel auxiliary capacitance is connected to the first auxiliary capacitance wiring, and the second pixel auxiliary capacitance is connected to the second auxiliary capacitance wiring.

From the perspective of achieving a higher aperture ratio, preferably the display device substrate includes a drain electrode connected to a drain region of the thin film transistor, the first auxiliary capacitance wiring is connected to a lower electrode of the first pixel auxiliary capacitance, and the upper electrode of the first pixel auxiliary capacitance is connected to the drain electrode through a second contact hole provided in the insulating film in a lower layer. Here, the upper electrode of the first pixel auxiliary capacitance may also be connected to the drain electrode in a lower layer through a contact hole.

The display device substrate may further include a third pixel auxiliary capacitance over the first pixel auxiliary capacitance, and the third pixel auxiliary capacitance may include the upper electrode of the first pixel auxiliary capacitance as its lower electrode. As a result, compared to the case in which only one pixel auxiliary capacitance is provided in one pixel, the sizes (areas) of the first pixel auxiliary capacitance, the second pixel auxiliary capacitance, and the third pixel auxiliary capacitance can be made small. Also, since the source wiring can have a two-layered structure, a higher aperture ratio can be obtained.

From the perspective of achieving a higher aperture ratio, preferably the display device substrate has a semiconductor layer, a gate insulating film and a first wiring, and the first wiring is disposed in a layer immediately above the gate insulating film, and is connected to the semiconductor layer via a third contact hole provided in the gate insulating film. This configuration is especially suitable when the display device substrate has an optical sensor circuit. The first wiring is not particularly limited, as long as it is a member that can be connected to the semiconductor layer, and it may be an electrode.

From the perspective of curbing the production costs even further while suppressing defects such as diffusion of the impurity from the substrate and broken wiring layer from occurring, preferably the display device substrate has a second wiring and a base semiconductor layer, and the second wiring is disposed in a layer immediately above the gate insulating film, and the base semiconductor layer is connected only to the second wiring via a fourth contact hole provided in the gate insulating film. This configuration is especially suitable when the display device substrate has an optical sensor circuit. The second wiring is not particularly limited as long as it is a member that can be connected to a semiconductor layer, and it may be an electrode.

The display device substrate may include an interlayer insulating film in which the first planarizing film and the first inorganic insulating film are layered in this order from the bottom, the first pixel auxiliary capacitance may include a dielectric substance, and the dielectric substance may be an insulating film continuous from the first inorganic insulating film. As a result, a dielectric substance for the first pixel auxiliary capacitance can easily be formed while suppressing damages due to the dry process from occurring.

From the similar perspective, the display device substrate may include an interlayer insulating film in which a planarizing film and an inorganic insulating film are layered in this order from the bottom, and the third pixel auxiliary capacitance may include a dielectric substance, and the dielectric substance may be an insulating film continuous from the inorganic insulating film.

In this specification, “planarizing film” refers to a film that can planarize (minimizes) the surface unevenness. Preferably, the surface of the planarizing film is substantially flat, but the film may have a step height of up to approximately 500 nm (preferably up to approximately 200 nm). When a planarizing film has an uneven section on the surface, the curvature radius of the uneven section is preferably greater than the step height. This way, when etching is conducted to form an upper wiring layer, etching residue can effectively be suppressed from being formed. The planarizing film may be a film called SOG (Spin on Glass) film, or may contain a photosensitive resin. When the planarizing film is etched by dry etching, the resist hardened when the etching was conducted has to be removed by ashing using the oxygen plasma before the resist can be removed with a resist stripper. In that case, however, because normally the resist and planarizing film cannot be etched selectively, the planarizing film can also be subjected to etching by oxygen plasma. However, by using photosensitive resin in the light exposure (exposure) and development (etching) processes, such a problem can be solved, because in that case no resist is used. Also, the planarizing film can also be wet etched. In the case of wet etching, ashing using oxygen plasma does not need to be performed prior to resist peeling. The resist can be removed by a resist removal process alone with a resist stripper. That is, wet etching is another way to solve the problem discussed above. From these perspectives, preferably the first planarizing film is a photosensitive resin film, and the first planarizing film is wet etched. More specifically, the first planarizing film in the region sandwiched between the upper electrode and the lower electrode of the first pixel auxiliary capacitance is preferably removed by wet etching.

The display device substrate may have an interlayer insulating film that includes a second planarizing film between the lower electrode of the first pixel auxiliary capacitance and the gate electrode (between the layers). Here, the planarizing film present below the lower electrode of the first pixel auxiliary capacitance planarizes the base (interlayer insulating film) of the lower electrode of the first pixel auxiliary capacitance. As a result, the first pixel auxiliary capacitance is less likely to be affected by the unevenness of the base. Consequently, occurrence of insulation breakdowns across the first pixel auxiliary capacitance can be suppressed. Also, in this case, the first pixel auxiliary capacitance can be laid out without any consideration of the base unevenness. Therefore, in this case, the display device substrate may include at least one of wirings, an electrode, or an element disposed below the lower electrode of the first pixel auxiliary capacitance, and the lower electrode of the first pixel auxiliary capacitance may extend beyond at least one of the wirings, the electrode, or the element, or may extend beyond the wirings, the electrode, and the element.

The present invention is also a display device including a display device substrate of the present invention. Therefore, a screen having a narrow frame and a high aperture ratio can be provided, while curbing the production cost.

### Effects of the Invention

With a display device substrate and a display device of the present invention, a display device substrate and a display device that have peripheral circuits in the frame region and is capable of achieving a high aperture ratio while curbing the production cost can be provided.

### BRIEF DESCRIPTION OF THE DRAWINGS

FIG. 1 is a schematic plan view of a display device substrate according to Embodiment 1.

FIG. 2 schematically shows the structure of elements constituting a peripheral circuit of a display device substrate according to Embodiment 1. FIG. 2(a) is a plan view, and FIG. 2(b) is a cross-sectional view taken along the line X1-Y1 of FIG. 2(a).

FIG. 3 schematically shows the configuration of a pixel on a display device substrate according to Embodiment 1. FIG. 3(b) is a plan view, FIG. 3(a) is a cross-sectional view taken along the line X2-Y2 of FIG. 3(b), and FIG. 3(c) is a cross-sectional view taken along the line X3-Y3 of FIG. 3(b).

FIG. 4 is a circuit diagram explaining the pixel circuit of a display device substrate according to Embodiment 1.

FIG. 5 is a schematic cross-sectional view illustrating the configuration of a display device substrate according to a comparison example.

FIG. 6 schematically shows the configuration of a pixel in a modification example of the display device substrate according to Embodiment 1. FIG. 6(b) is a plan view and FIG. 6(a) is a cross-sectional view taken along the line X4-Y4 of FIG. 6(b).

FIG. 7 is a circuit diagram illustrating the pixel circuit in a modification example of the display device substrate according to Embodiment 1.

FIG. 8 schematically shows the configuration of a pixel in a display device substrate according to Embodiment 2. FIG. 8(b) is a plan view, FIG. 8(a) is a cross-sectional view taken along the line X5-Y5 of FIG. 8(b), and FIG. 8(c) is a cross-sectional view taken along the line X6-Y6 of FIG. 8(b).

FIG. 9 is a circuit diagram explaining the pixel circuit configuration of a display device substrate according to Embodiment 2.

FIG. 10 schematically shows the configuration of a pixel in Modification Example 1 of the display device substrate according to Embodiment 2. FIG. 10(b) is a plan view, FIG. 10(a) is a cross-sectional view taken along the line X7-Y7 of FIG. 10(b), and FIG. 10(c) is a cross-sectional view taken along the line X8-Y8 of FIG. 10(b).

FIG. 11 is a circuit diagram illustrating the pixel circuit in Modification Example 1 of the display device substrate according to Embodiment 2.

FIG. 12 schematically shows the configuration of a pixel in Modification Example 2 of display device substrate according to Embodiment 2. FIG. 12(b) is a plan view, FIG. 12(a) is a cross-sectional view taken along the line X9-Y9 of FIG. 12(b), and FIG. 12(c) is a cross-sectional view taken along the line X10-Y10 of FIG. 12(b).

FIG. 13 is a circuit diagram explaining the pixel circuit in Modification Example 2 of the display device substrate according to Embodiment 2.

FIG. 14 schematically shows the configuration of a pixel in Modification Example 3 of the display device substrate according to Embodiment 2. FIG. 14(b) is a plan view, FIG. 14(a) is a cross-sectional view taken along the line X11-Y11 of FIG. 14(b), and FIG. 14(c) is a cross-sectional view taken along the line X12-Y12 of FIG. 14(b).

FIG. 15 is a circuit diagram explaining the pixel circuit in Modification Example 3 of the display device substrate according to Embodiment 2.

FIG. 16 is a cross-sectional view illustrating the configuration of a pixel in Modification Example 4 of the display device substrate according to Embodiment 2.

FIG. 17 schematically shows the configuration of a pixel in a display device substrate according to Embodiment 3. FIG. 17(b) is a plan view, FIG. 17(a) is a cross-sectional view taken along the line X13-Y13 of FIG. 17(b), and FIG. 17(c) is a cross-sectional view taken along the line X14-Y14 of FIG. 17(b).

FIG. 18 is a circuit diagram explaining the pixel circuit of a display device substrate according to Embodiment 3.

FIG. 19 schematically shows the configuration of a pixel in a modification example of the display device substrate according to Embodiment 3. FIG. 19(b) is a plan view, FIG. 19(a) is a cross-sectional view taken along the line X15-Y15 of FIG. 19(b), and FIG. 19(c) is a cross-sectional view taken along the line X16-Y16 of FIG. 19(b).

FIG. 20 is a schematic cross-sectional view illustrating the configuration of the display device substrate in a comparison example.

FIG. 21 schematically shows the configuration of a pixel in a display device substrate according to Comparison Example 1. FIG. 21(b) is a plan view, FIG. 21 (a) is a cross-sectional view taken along the line X17-Y17 of FIG. 21 (b), and FIG. 21 (c) is a cross-sectional view taken along the line X18-Y18 of FIG. 21 (b).

FIG. 22 is a circuit diagram explaining the pixel circuit in a display device substrate according to Comparison Example 1.

### DETAILED DESCRIPTION OF EMBODIMENTS

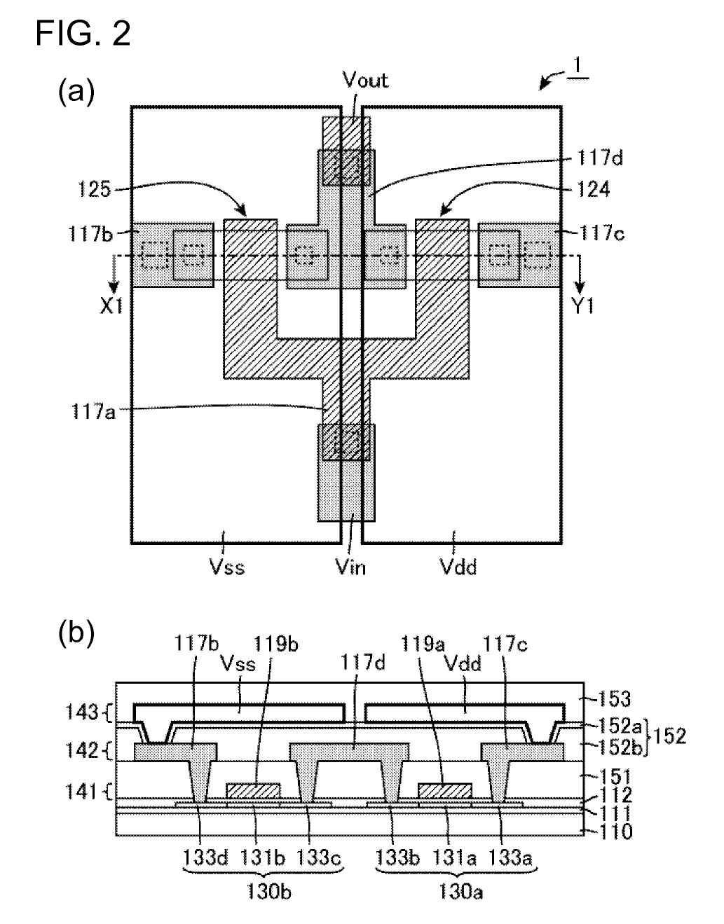

Although embodiments are enumerated to describe the present invention further in detail with reference to figures, it should be understood that the present invention is not limited to such embodiments. Hatched regions in FIGS. 2, 3, 6, 8, 10, 12, 14, 16, 17, 19, and 21 are first wiring layers, shaded regions are second wiring layers, and regions surrounded by bold lines are third wiring layers. Square regions enclosed by dotted lines in plan views in FIGS. 2, 3, 6, 8, 10, 12, 14, 17, 19 and 21 are contact holes.

### Embodiment 1

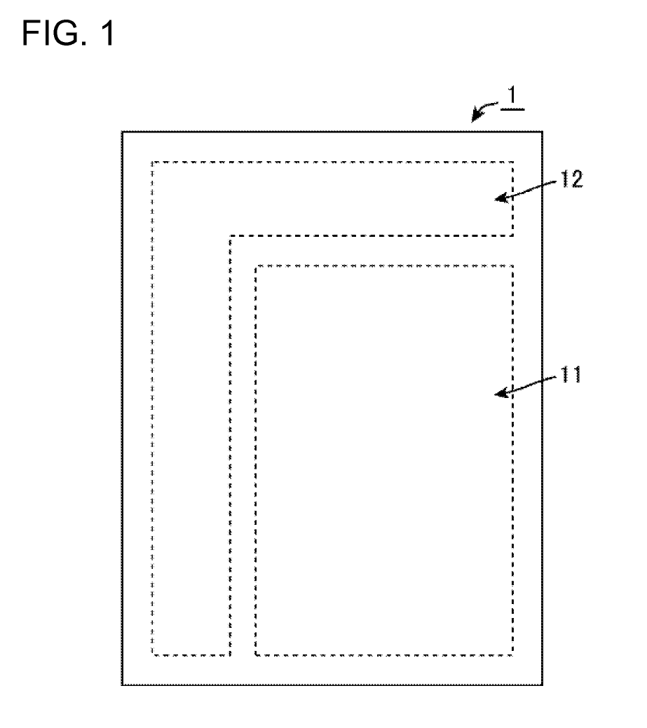

FIG. 1 is a schematic plan view illustrating a display device substrate according to Embodiment 1. As shown in FIG. 1, a display device substrate 1 according to Embodiment 1 has a display section 11 where a plurality of pixels are arranged in a matrix, and a frame region 12 that surrounds the display section 11. In the frame region 12, peripheral circuits including drivers, such as source drivers and gate drivers and a power circuit, are formed. That is, the display device substrate 1 is a TFT array substrate for an active matrix type liquid crystal display device.

FIG. 2 schematically shows the configuration of elements constituting a peripheral circuit of a display device substrate according to Embodiment 1. FIG. 2(a) is a plan view, and FIG. 2(b) is a cross-sectional view taken along the line X1-Y1 of FIG. 2(a). Here, an example in which a multi-layer wiring is used as a power supply wiring for an inverter circuit is described. As shown in FIG. 2, the display device substrate 1 has, on a main surface of a substrate 110, an N-channel type thin film transistor (NchTFT) 124, a P-channel type thin film transistor (PchTFT) 125, a low-voltage power supply wiring Vₛₛ, a high-voltage power supply wiring V_{dd}, an input voltage wiring Vᵢₙ, and an output voltage wiring Vₒᵤₜ. Thus, the display device substrate 1 has CMOS transistors.

Now, the cross-sectional structure is described. The display device substrate 1 has a multi-layered structure in which, on a main surface of a substrate 110, a base layer 111, semiconductor layers 130a and 130b, a gate insulating film 112, a first wiring layer 141, a first interlayer insulating film 151 in which a planarizing film is layered over an inorganic insulating film, a second wiring layer 142, and a second interlayer insulating film 152 in which an inorganic insulating film 152a is layered over a planarizing film 152b, a third wiring layer 143, and a third interlayer insulating film 153 made of a planarizing film are layered in this order from the side close to the substrate 110. The semiconductor layer 130a includes a channel region 131a and high-concentration impurity regions 133a and 133b. The semiconductor layer 130b includes a channel region 131b and high-concentration impurity regions 133c and 133d.

In this specification, “upper” refers to a location distal to the substrate, and “lower” refers to a location proximal to the substrate.

NchTFT 124 is composed of the channel region 131a, the high-concentration impurity regions 133a and 133b, the gate insulating film 112, and a gate electrode 119a. Here, Nch-TFT 124 is a top gate (planar) TFT having a single drain structure. The high-concentration impurity region 133a functions as a source region, and the high-concentration impurity region 133b functions as a drain region. PchTFT 125 is also a top gate (planar) TFT with a single drain structure, which is composed of the channel region 131b, the high-concentration impurity regions 133c and 133d, the gate insulating film 112, and the gate electrode 119b. The high-concentration impurity region 133d functions as a source region, and the high-concentration impurity region 133c functions as a drain region.

The gate electrodes 119a and 119b are formed of the first wiring layer 141. Also, the gate electrodes 119a and 119b are connected to each other by being unitarily formed with a connecting section 117a, which is formed of the first wiring layer 141. An input voltage wiring Vᵢₙ formed of the second wiring layer 142 is connected to the gate electrodes 119a and 119b via the connecting section 117a. The connecting section 117a and the input voltage wiring Vᵢₙ are connected together via a contact hole provided in the first interlayer insulating film 151.

A low-voltage power supply wiring Vₛₛ is formed of the third wiring layer 143. The low-voltage power supply wiring Vₛₛ and the source region of PchTFT 125 (high-concentration impurity region 133d) are connected together via a connecting section 117b, which is formed of the second wiring layer 142. The low-voltage power supply wiring Vₛₛ and the connecting section 117b are connected together via a contact hole in the second interlayer insulating film 152. The source region of PchTFT 125 and the connecting section 117b are connected together via a contact hole that runs through the gate insulating film 112 and the first interlayer insulating film 151.

A high-voltage power supply wiring V_{dd} is formed of the third wiring layer 143. The high-voltage power supply wiring V_{dd} and the source region of NchTFT 124 (high-concentration impurity region 133a) are connected via a connecting section 117c, which is formed of the second wiring layer 142. The low-voltage power supply wiring V_{dd} and the connecting section 117c are connected together via a contact hole provided in the second interlayer insulating film 152. The source region of NchTFT 124 and the connecting section 117c are connected together via a contact hole running through the gate insulating film 112 and first interlayer insulating film 151.

An output voltage wiring Vₒᵤₜ is formed of the first wiring layer 141. The output voltage wiring Vₒᵤₜ is connected to the drain region of NchTFT 124 (high-concentration impurity region 133b) and to the drain region of PchTFT 125 (high-concentration impurity region 133c) via a connecting section 117d formed of the second wiring layer 142. The output voltage wiring Vₒᵤₜ and connecting section 117d are connected together via a contact hole provided in the first interlayer insulating film 151. The drain region of NchTFT 124 and the drain region of PchTFT 125 are respectively connected to the connecting section 117d via a contact hole running through the gate insulating film 112 and the first interlayer insulating film 151.

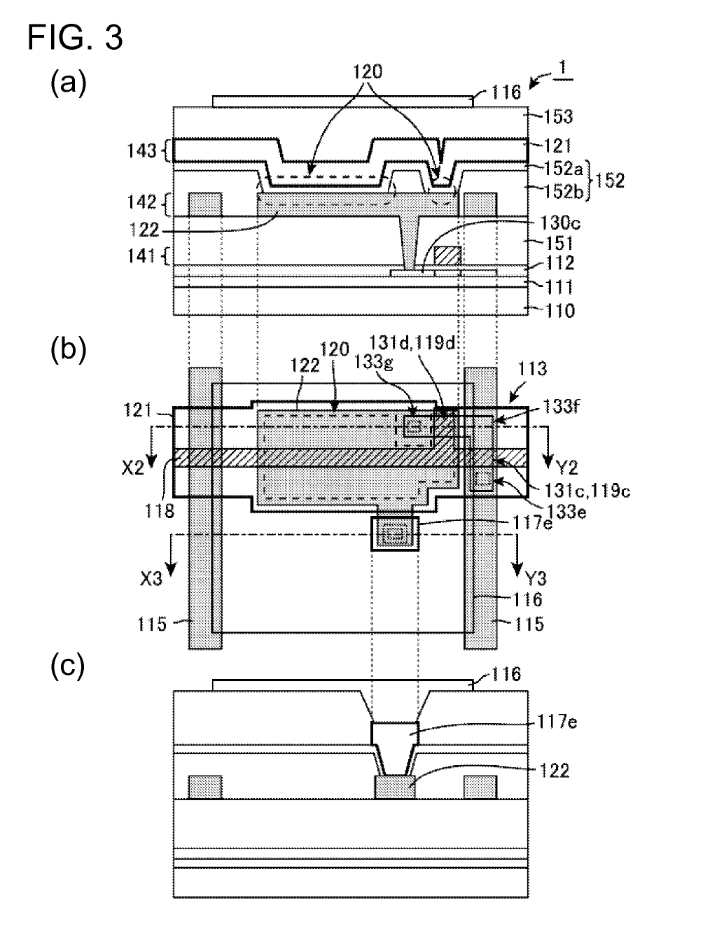

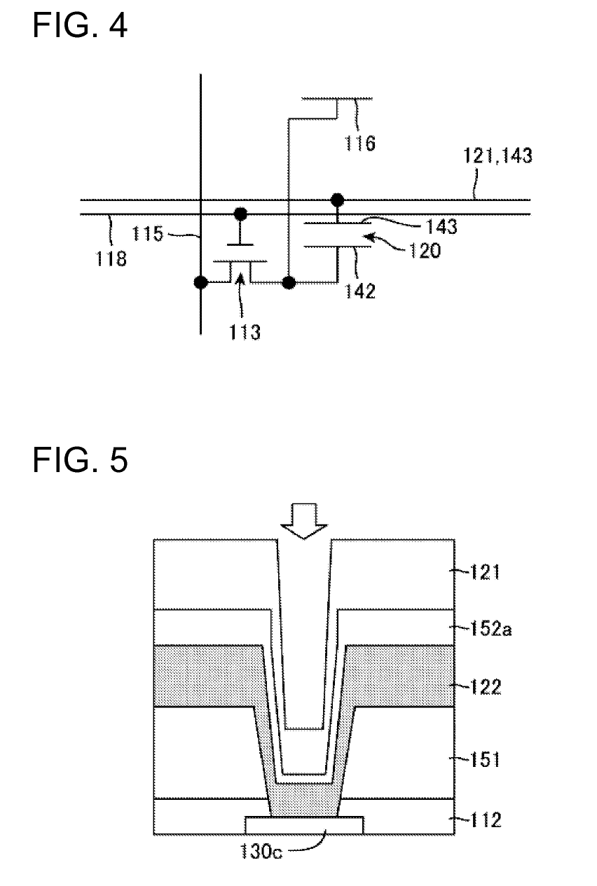

Next, a configuration of the pixel provided in the display section 11 is described. FIG. 3 schematically shows the configuration of a pixel on a display device substrate according to Embodiment 1. FIG. 3(b) is a plan view, FIG. 3(a) is a cross-sectional view taken along the line X2-Y2 of FIG. 3(b), and FIG. 3(c) is a cross-sectional view taken along the line X3-Y3 of FIG. 3(b). FIG. 4 is a circuit diagram explaining the pixel circuit on a display device substrate according to Embodiment 1.

As shown in FIG. 3(b), the display device substrate 1 includes, over a main surface of the substrate 110, a plurality of gate wirings 118, which are in parallel with each other; a plurality of storage capacitance wirings 121, which are disposed parallel to the respective gate wirings 118; a plurality of source wirings 115, which are in parallel with each other and perpendicular to the respective gate wirings 118; a pixel switching TFT 113, which is disposed near the intersection of the gate wiring 118 and the source wiring 115 in each pixel; a plurality of pixel auxiliary capacitances 120 provided in each pixel in a region overlapping the respective auxiliary capacitance wiring 121; and a plurality of pixel electrodes 116 provided in regions partitioned by the gate wirings 118 and the source wirings 115.

As shown in FIG. 4, in each pixel on the display device substrate 1, the source of TFT 113 is connected to the source wiring 115, the gate of TFT 113 is connected to the gate wiring 118, the pixel electrode 116 is connected to the drain of TFT 113, and the pixel auxiliary capacitance 120 is connected to the drain of TFT 113 and to the auxiliary capacitance wiring 121.

The display device substrate 1 may be a substrate for a color display device, and the pixel may be a picture element.

Now, the cross-sectional structure is described. As shown in FIGS. 3(a) and 3(c), the display device substrate 1 has a multi-layered structure in the display section 11, as in the case of the frame region 12, in which a base layer 111, a semiconductor layer 130c, a gate insulating film 112, a first wiring layer 141, a first interlayer insulating film 151, a second wiring layer 142, a second interlayer insulating film 152, a third wiring layer 143, and a third interlayer insulating film 153 are layered on a main surface of the substrate 110 in this order from the side closer to the substrate 110. Furthermore, the display device substrate 1 has a pixel electrode 116 on the third interlayer insulating film 153.

TFT 113 is composed of channel regions 131c and 131d, high-concentration impurity regions 133e, 133f, and 133g, a gate insulating film 112 and gate electrodes 119c and 119d. That is, the TFT 113 is a top gate (planar) TFT with a single drain structure. The TFT 113 also has a dual gate structure in which two channel regions 131c and 131d are connected serially. The high-concentration impurity region 133e functions as a source region, and the high-concentration impurity region 133g functions as a drain region. Regions of the gate wiring 118 that overlap the semiconductor layer 130c function as gate electrodes 119c and 119d. That is, in this specification, the gate electrode is the conductive section of the region facing the channel region constituting the pixel switching transistor via the gate insulating film. Furthermore, TFT 113 is disposed at a location overlapping the auxiliary capacitance wiring 121 formed of the third wiring layer 143.

In this specification, the semiconductor layer may be a layer formed of at least a semiconductor material and, like the source region and the drain region, may function as a conductive material.

The gate wiring 118 is the wiring that transmits the scanning signals. The gate wiring 118 (gate electrodes 119c and 119d) is formed of the first wiring layer 141. Also, the gate wiring 118 (gate electrodes 119c and 119d) is disposed at a location that overlaps the auxiliary capacitance wiring 121.

The source wiring 115 is the wiring that transmits the pixel signals (image data), and is formed of the second wiring layer 142. The source wiring 115 and the source region of TFT 113 (high-concentration impurity region 133e) are connected together via a contact hole running through the gate insulating film 112 and the first interlayer insulating film 151.

A drain electrode 122 is formed of the second wiring layer 142, overlapping the auxiliary capacitance wiring 121. The drain electrode 122 is connected to the drain region of TFT 113 (high-concentration impurity region 133g) through a contact hole running through the gate insulating film 112 and the first interlayer insulating film 151.

The drain electrode 122 is connected to the pixel electrode 116 via a connecting section 117e formed of the second wiring layer 142. The pixel electrode 116 and the connecting section 117e are connected together via a contact hole provided in the third interlayer insulating film 153. The drain electrode 122 and the connecting section 117e are connected together via a contact hole provided in the second interlayer insulating film 152.

The auxiliary capacitance wiring 121 is formed of the third wiring layer 143. A planarizing film 152b is partially removed in the region where the auxiliary capacitance wiring 121 and the drain electrode 122 overlap. A pixel auxiliary capacitance 120 is formed in the region where the drain electrode 122 and the auxiliary capacitance wiring 121 are disposed to face each other via an inorganic insulating film 152a only (regions surrounded by dashed lines in FIGS. 2(a) and 2(b)). Thus, the drain electrode 122 functions as the lower electrode of the pixel auxiliary capacitance 120, the auxiliary capacitance wiring 121 functions as the upper electrode of the pixel auxiliary capacitance 120, and the inorganic insulating film 152a functions as an insulating film (dielectric) of the pixel auxiliary capacitance 120.

The contact hole connecting the drain electrode 122 and the drain region of TFT 113 is provided outside the pixel auxiliary capacitance 120. That is, the planarizing film 152b in the region where the contact hole connecting the drain electrode 122 and the drain region of TFT 113 is provided is not removed. If the contact hole connecting the drain electrode 122 and the drain region of TFT 113 were provided in the pixel auxiliary capacitance 120, actually the coverage of the insulating film of the pixel auxiliary capacitance 120 (inorganic insulating film 152a) would be reduced, as shown in FIG. 5.

The auxiliary capacitance wiring 121 may or may not be larger than a region of the drain electrode 122 that excludes the portion connected to the connecting section 117e. But preferably, they have about the same size from the perspectives of the aperture ratio and the pixel auxiliary capacitance.

The method for manufacturing a display device substrate 1 of Embodiment 1 is described below.

First, the substrate 110 is subjected to a pre-treatment, i.e., washing and pre-annealing. The material of the substrate 110 is not particularly limited, but considering costs and other issues, a glass substrate or a resin substrate is suitable. Next, the following steps (1)-(14) are conducted.

(1) Forming a Basecoat Film

On the substrate 110, by Plasma Enhanced Chemical Vapor Deposition (PECVD), a SiON film having a thickness of 20-100 nm (preferably 30-60 nm; 50 nm, for example) and a SiOx film having a thickness of 50-150 nm (preferably 70-120 nm; 100 nm, for example) are formed in this order to form a base layer 111. As the material gas to form the SiON film, a mixed gas of silane (SiH₄), nitrous oxide (N₂O) and ammonia (NH₃), for example, may be used. The SiOx film is preferably formed using Tetra Ethyl Ortho Silicate (TEOS) gas as a material gas. The base layer 111 may contain a silicon nitride (SiNx) film formed using a mixed gas of silane (SiH₄) and ammonia (NH₃), for example, as a material gas.

(2) Forming a Semiconductor Layer

An amorphous silicon (a-Si) film having a thickness of 20-70 nm (preferably 30-60 nm; 50 nm, for example) is formed using the PECVD method. As a material gas to form an a-Si film, SiH₄, disilane (Si₂H₆), for example, can be used. Since hydrogen is contained in the a-Si film formed by the PECVD method, a treatment to reduce the hydrogen concentration of the a-Si film (dehydrogenation treatment) is conducted at approximately 500° C. Next, laser annealing is conducted to melt the a-Si film, which is then cooled for recrystallization to form a polysilicon (p-Si) film. For laser annealing, excimer laser, for example, is used. For formation of a p-Si film, as a pre-treatment for laser annealing (in order to make a continuous grain silicon (CG-silicon)), a metal catalyst such as nickel may be applied instead of dehydrogenation treatment for solid-phase growth by heat treatment. For crystallization of the a-Si film, the solid-phase growth by heat treatment alone may be performed. Next, dry etching is conducted using a mixed gas of carbon tetrafluoride (CF₄) and oxygen (O₂) to pattern the p-Si film and to form semiconductor layers 130a, 130b, and 130c.

(3) Forming a Gate Insulating Film

Next, a gate insulating film 112 made of silicon oxide having a thickness of 20-120 nm (preferably 30-80 nm; 45 nm, for example) is formed to cover semiconductor layers 130a, 130b, and 130c by PECVD method, using a TEOS gas as a material gas. Materials for the gate insulating film 112 are not particularly limited, and a SiNx film, SiON film and the like may also be used. As material gases for forming SiNx or SiON film, similar material gases discussed in the description of the basecoat film formation can be used. The gate insulating film 112 may also be a laminated body composed of the aforementioned plurality of materials.

(4) Ion Doping

In order to control the TFT threshold, an impurity such as boron is doped into the semiconductor layers 130a, 130b, and 130c by ion doping, ion implantation or like method. More specifically, after an impurity such as boron is doped into the semiconductor layers 130a, 130b, and 130c (the first doping process), an impurity such as boron is doped again into the semiconductor layer 130a, which is destined to become NchTFT 124, and into the semiconductor layer 130c, which is destined to become TFT 113, while the semiconductor layer 130b, which is destined to become the PchTFT 125, is masked by a resist (second doping process). The first doping does not need to be conducted if threshold control is not necessary for PchTFT 125.

(5) Forming a First Wiring Layer

Next, a tantalum nitride (TaN) film having a thickness of 10-70 nm (preferably 20-50 nm; 30 nm, for example) and a tungsten (W) film having a thickness of 200-500 nm (preferably 300-400 nm; 370 nm, for example) are deposited in this order by sputtering. Subsequently, a resist mask is formed by patterning a resist film into a desired shape using photolithography. Then, a first wiring layer 141 is formed by dry etching using an etching gas, which is a mixed gas containing adjusted amounts of gases such as argon (Ar), sulfur hexafluoride (SF₆), carbon tetrafluoride (CF₄), oxygen (O₂), and chlorine (Cl₂). The material for the first wiring layer 141 can be a metal having an even surface, stable properties and a high melting point, such as tantalum (Ta), molybdenum (Mo), or molybdenum tungsten (MoW), or a low resistive metal such as aluminum (Al). The first wiring layer 141 may also be a laminated body made of the aforementioned plurality of materials.

(6) Forming Source and Drain Regions

Next, in order to form source and drain regions of TFTs 113, 124, and 125, an impurity such as phosphorus for N-channel type TFT, and an impurity such as boron for P-channel type TFT is doped in high-concentration into the semiconductor layers 130a, 130b, and 130c by ion doping, ion implantation, or the like using the first wiring layer 141 as a mask. At this time, LDD (Lightly Doped Drain) regions may be formed as necessary. Subsequently, in order to activate the impurity ions present in the semiconductor layers 130a, 130b, and 130c, a heat activation treatment is conducted at approximately 700° C. for 6 hours. With this process, the electrical conductivity of the source regions and the drain regions can be improved. Radiation by excimer laser is also a possible means of activation.

(7) Forming a First Interlayer Insulating Film

Next, over the entire substrate 110 surface, a SiNx film having a thickness of 100-400 nm (preferably 200-300 nm; 250 nm, for example) is formed as an inorganic insulating film by the PECVD method. Then, a first interlayer insulating film 151 is formed by forming a SOG (Spin-on glass) film having a thickness of 300-1500 nm (preferably 400-700 nm; 500 nm, for example) as a planarizing film by a spin coater machine, using methylpolysiloxane (MSQ) material. As a result, the base of the lower electrode (drain electrode 122) of the pixel auxiliary capacitance 120 can be made flat. Therefore, even if the lower electrode of the pixel auxiliary capacitance 120 extends beyond the gate wiring 118 or TFT 113, insulation breakdown across the pixel auxiliary capacitance 120 can be suppressed from occurring. That is, the pixel auxiliary capacitance 121 can be laid out with a higher degree of freedom, while suppressing defect occurrences. An SiON film or the like can also be used as the inorganic insulating film. Also, in order to suppress the lowering of the TFT properties due to the transient response deterioration or the like and to stabilize the electrical properties of TFTs 113, 124, and 125, a thin cap film (a TEOS film, for example) having a thickness of about 50 nm may be formed under the inorganic insulating film.

(8) Forming Contact Holes

Next, after a resist mask is formed by patterning a resist film into a desired shape using photolithography, the gate insulating film 112 and the first interlayer insulating film 151 are etched by dry etching, and contact holes running through the gate insulating film 112 and the first interlayer insulating film 151 are formed. Instead of dry etching, wet etching using, for example, a hydrofluoric acid-based etching solution may be conducted.

(9) Forming a Second Wiring Layer

Next, by sputtering or the like, a titanium (Ti) film having a thickness of 30-200 nm (preferably 50-150 nm; 100 nm, for example), an aluminum (Al) film having a thickness of 200-1000 nm (preferably 300-600 nm; 350 nm, for example), and a Ti film having a thickness of 30-200 nm (preferably 50-150 nm; 100 nm, for example) are deposited in this order. Next, after a resist film is patterned into a desired shape by photolithography to form a resist mask, the multi-layered metal film of Ti/Al/Ti is patterned by dry etching to form a second wiring layer 142. As a metal constituting the second wiring layer 142, an Al—Si alloy or the like may be used instead of Al. Although Al is used here to lower the resistance of the wiring, the aforementioned materials of the first wiring layer 141 (Ta, Mo, MoW, W, TaN, or the like) may be used if high heat resistance is required and an increase in resistance is allowed to a certain extent (when a short wiring configuration is used, for example) as a metal constituting the second wiring layer 142.

(10) Forming a Second Interlayer Insulating Film and an Insulating Film of the Pixel Auxiliary Capacitance

Next, a photosensitive resin, such as photosensitive acrylic resin film, having a thickness of 0.5-3 μm (2.5 μm, for example) is formed (applied) over the entire substrate 110 surface by spin coating or the like to form a planarizing film 152b. As materials for the planarizing film 152b, resins such as photosensitive polyalkylsiloxane-based, polysilazane-based, polyimide-based, and Parellin-based resins, epoxy resin, a mixed resin of acryl and epoxy can be used. Subsequently, through a photomask patterned into a desired light-shielding shape, the planarizing film 152b is exposed to light (light exposure), and etching (development process) is conducted to remove the planarizing film 152b for the regions destined to become the contact holes in the second interlayer insulating film 152, and for the regions destined to become the pixel auxiliary capacitance 120. Next, planarizing film 152b is baked (for example, at 200° C., for 30 minutes), and then an inorganic insulating film 152a having a thickness of 30-150 nm (preferably 40-90 nm; 80 nm, for example) is formed of silicon oxide (SiO₂) by PECVD method using a TEOS gas as the material gas. Alternatively, an SiO₂ film or SiN film, which is formed by a technique that can form high-quality films at a low temperature, such as sputtering, CAT-CVD method, ICP plasma CVD method (using an ICP-CVD equipment, manufactured by Selvac, for example), or ozone oxidization method (using Meiden Pure Ozone Generator, manufactured by Meidensha, for example), can be deposited as the inorganic insulating film 152a. Subsequently, a resist mask is formed by patterning a resist film into a desired shape by photolithography, and then the inorganic insulating film 152a in regions destined to become contact holes in the second interlayer insulating film 152 is removed by dry etching using carbon tetrafluoride (CF₄) or the like, to align the region where the planarizing film 152b has been removed. As a result, contact holes running through the planarizing film 152b and the inorganic insulating film 152a (second interlayer insulating film 152) are formed, and the inorganic insulating film 152a is disposed immediately above the region of the drain electrode 122 that is destined to become the pixel auxiliary capacitance 120. Also, by forming the inorganic insulating film 152a (passivation film) on the planarizing film 152b, damages resulting from the dry process can be suppressed from occurring. More specifically, because the entire planarizing film 152b is covered by the inorganic insulating film 152a, when the inorganic insulating film 152a or the third wiring layer 143 are dry etched, damages on the planarizing film 152b due to the dry etching is suppressed from occurring. The planarizing film 152b can also be prevented from suffering any damage from the oxygen plasma during the resist ashing in the contact formation process of the second interlayer insulating film 152 and the formation process of the third wiring layer 143. The planarizing film 152b and the inorganic insulating film 152a may respectively have a structure in which a plurality of films made of different materials are layered.

(11) Forming a Third Wiring Layer

Next, a titanium (Ti) film having a thickness of 30-200 nm (preferably 50-150 nm; 100 nm for example), an aluminum (Al) film having a thickness of 200-1000 nm (preferably 300-600 nm; 350 nm, for example), and a Ti film having a thickness of 30-200 nm (preferably 50-150 nm; 100 nm, for example) are deposited in this order by sputtering or the like. Subsequently, a resist mask is formed by patterning a resist film into a desired shape by photolithography, and then the Ti/Al/Ti multi-layered metal film is patterned by dry etching to form a third wiring layer 143. As a metal constituting the third wiring layer 143, an Al—Si alloy or the like may be used instead of Al. Although Al is used here to lower the resistance of the wiring, the aforementioned materials for the first wiring layer 141 (Ta, Mo, MoW, W, TaN, or the like) may be used if high heat resistance is required and an increase in resistance is allowed to a certain extent (when a short wiring configuration is used, for example) as a metal constituting the third wiring layer 143. When the third wiring layer 143 is patterned by wet etching, and a triple mixture etchant of phosphoric acid, nitric acid, and acetic acid, for example, is used, Ti is not etched away. Therefore, when the third wiring layer 143 is patterned by wet etching, instead of using a Ti film as the constituent material of the third wiring layer 143, a multi-layered film having double layers composed of, from the bottom, an Al film (i.e., 350 nm thick) and a Mo film (i.e., 50 nm thick), or having triple layers composed of, from the bottom, a Mo film (i.e., 50 nm thick), an Al film (i.e., 350 nm thick), and a Mo film (i.e., 50 nm), for example, can be used as the third wiring layer 143. The Mo film and the Al film may be alloys.

(12) Forming a Third Interlayer Insulating Film

Next, by spin coating or the like, a photosensitive acrylic resin film having a thickness of 0.5-3 μm (i.e., 2.5 μm) is deposited to form a third interlayer insulating film 153, which is made of a planarizing film. The third interlayer insulating film 153 can be made of a photosensitive resin such as polyalkylsiloxane-based, polysilazane-based, polyimide-based, or Parellin-based resin, epoxy resin, a mixed resin of acryl and epoxy or the like.

(13) Forming a Contact Hole

Next, through a photomask patterned into a desired light-shielding shape, the third interlayer insulating film 153 is exposed to light (light exposure), and etching (development process) is conducted to form a contact hole that runs through the third interlayer insulating film 153.

(14) Forming a Pixel Section

Next, by sputtering or like method, a transparent conductive film such as an ITO film or IZO film, for example, having a thickness of 50-200 nm (preferably 100-150 nm; 100 nm, for example), is formed, and then the film is patterned by photolithography into a desired shape to form a pixel electrode 116. After undergoing the manufacturing steps described above, a display device substrate 1 is now complete.

When a liquid crystal display device is manufactured using the display device substrate 1, regular panel assembly or module assembly can be performed after this.

In the display device substrate 1, which is an embodiment of the present invention, an auxiliary capacitance wiring 121 (the upper electrode of the pixel auxiliary capacitance 120) is formed of the third wiring layer 143. The lower electrode of the pixel auxiliary capacitance 120 (drain electrode 122) is formed of the second wiring layer 142, which is disposed above the gate electrode 119c or 119d. Therefore, members located below the second wiring layer 142, such as TFT 113 and the gate wiring 118 (gate electrodes 119c and 119d), can be disposed to overlap the pixel auxiliary capacitance 120. As a result, even if the pixel auxiliary capacitance 120 is made larger, members, such as TFT 113 and the gate wiring 118 (gate electrodes 119c and 119d) can contribute to a higher aperture ratio. That is, both the increase in the pixel auxiliary capacitance 120 and the improvement of the aperture ratio can be achieved.

Here, when the pixel auxiliary capacitance 120 is formed by the multi-layer wiring technology using a dry process as discussed above, independent of the constituting elements of pixels, any additional manufacturing steps are not necessary to form the pixel auxiliary capacitance 120. That is, when applying the present invention to a display device substrate in which a multi-layer wiring technology using a dry process is utilized, the manufacturing costs do not increase.

On the other hand, when a multi-layer wiring technology using a wet process is utilized, an inorganic insulating film 152a (passivation film), which is for preventing any damages due to the dry process from occurring, does not need to be formed. Therefore, an inorganic insulating film 152a has to be formed separately before or after a thick planarizing film 152b is formed. However, because the peripheral circuit and the display section 11 can have a common wiring by forming the upper electrode and the lower electrode of the pixel auxiliary capacitance 120 from the second wiring layer 142 and the third wiring layer 143, and by utilizing a thin inorganic insulating film 152a, which is separately formed, as the insulating film of the pixel auxiliary capacitance 120, the manufacturing costs can be partially reduced. Also in this case, of course, because members such as TFT 113 and the gate wiring 118 (gate electrodes 119c and 119d) can be formed below the pixel auxiliary capacitance 120, the aperture ratio can be improved.

Below, a modified example of this embodiment is described.

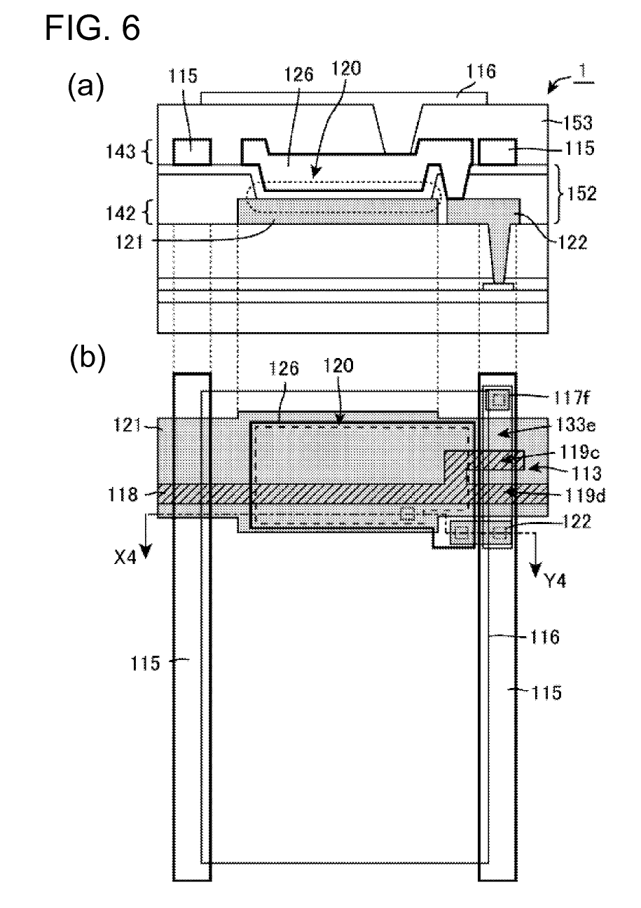

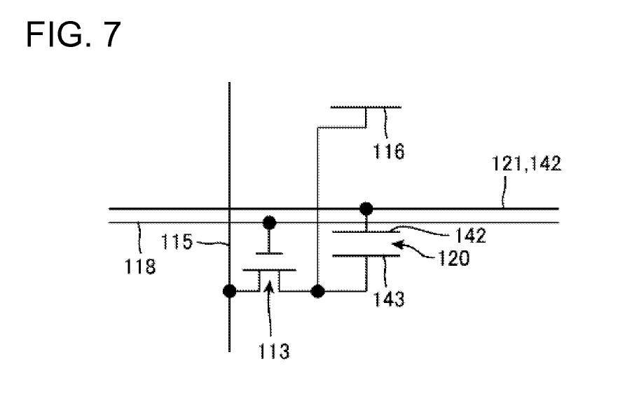

FIG. 6 is a schematic view illustrating the pixel structure in a modification example of the display device substrate of Embodiment 1. FIG. 6(b) is a plan view, and FIG. 6(a) is a cross-sectional view taken along the line X4-Y4 of FIG. 6(b). FIG. 7 is a circuit diagram explaining the pixel circuit in a modification example of a display device substrate of Embodiment 1. Here, since this modification example is different from the embodiment described above only with respect to the pixel structure, illustration and description of the peripheral circuit is omitted.

As shown in FIGS. 6 and 7, in the display device substrate 1, the source wiring 115 may be formed of the third wiring layer 143, and the auxiliary capacitance wiring 121 may be formed of the second wiring layer 142. In this case, the auxiliary capacitance wiring 121 also functions as the lower electrode of the pixel auxiliary capacitance 120, and the upper electrode 126 of the pixel auxiliary capacitance 120 formed of the third wiring layer 143 is connected to the drain electrode 122 through a contact hole provided in the second interlayer insulating film 152. Also, the pixel electrode 116 is connected to the upper electrode 126 through a contact hole provided in the third interlayer insulating film 153. Furthermore, the source wiring 115 is connected to the source region of TFT 113 (high-concentration impurity region 133e) via a connecting section 117f formed of the second wiring layer 142.

Also in this modification example, because members such as TFT 113 and gate wiring 118 (gate electrodes 119c and 119d) can be formed below the pixel auxiliary capacitance 120, both the increase in the pixel auxiliary capacitance 120 and the aperture ratio improvement can be achieved. Also, since this modification example can be manufactured by a similar manufacturing process as the embodiment described above, the production costs can be curbed as well.

### Embodiment 2

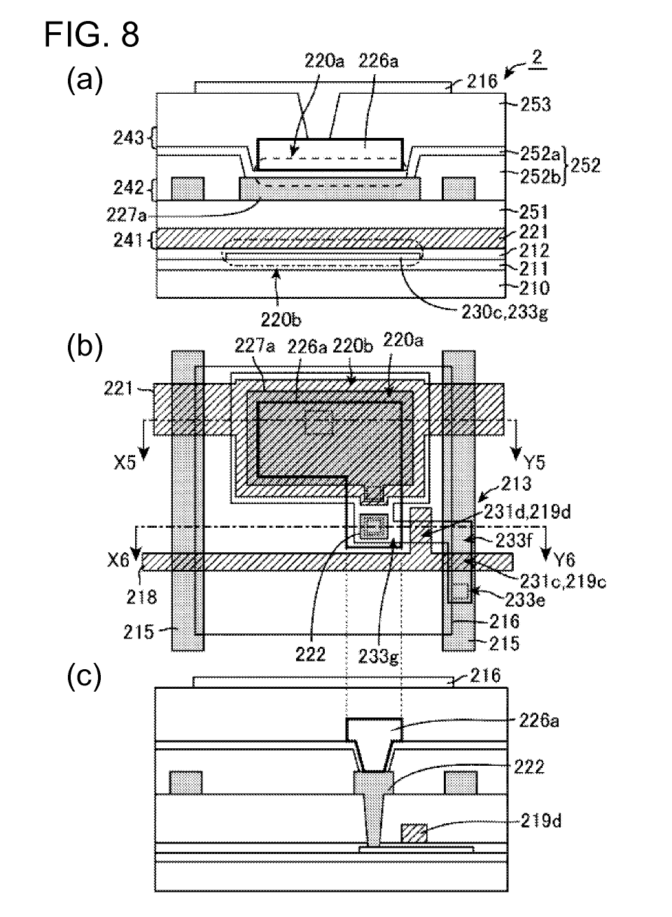

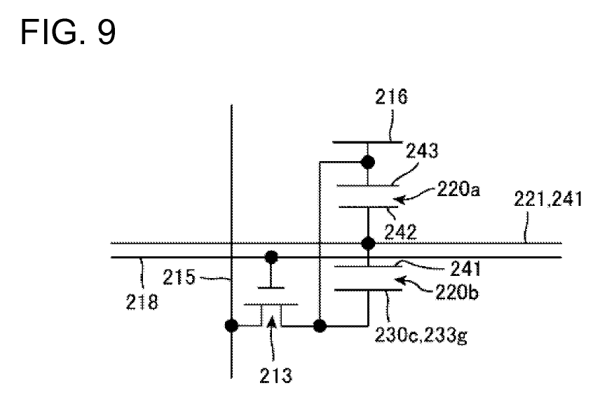

FIG. 8 is a schematic view showing the pixel configuration in a display device substrate according to Embodiment 2. FIG. 8(b) is a plan view, FIG. 8(a) is a cross-sectional view taken along the line X5-Y5 of FIG. 8(b), and FIG. 8(c) is a cross-sectional view taken along the line X6-Y6 of FIG. 8(b). FIG. 9 is a circuit diagram explaining the pixel circuit in a display device substrate according to Embodiment 2. Since this embodiment is different from Embodiment 1 only with respect to the pixel configuration, illustration and description on the entire configuration and the peripheral circuit is omitted, and the description provided is mainly on the display section.

As shown in FIG. 8(b), in the display device substrate 2 of Embodiment 2, a substrate 210 has on one of its main surfaces: a plurality of gate wirings 218, which are disposed in parallel with each other; a plurality of storage capacitance wirings 221, which are disposed in parallel with respective gate wirings 218; a plurality of source wirings 215, which are parallel to each other and perpendicular to respective gate wirings 218; a pixel switching TFT 213, which is provided near the intersection of the gate wiring 218 and the source wiring 215 in each pixel; a plurality of pixel auxiliary capacitances 220a and 220b provided in a region in each pixel that overlaps the respective auxiliary capacitance wiring 221; and a plurality of pixel electrodes 216 provided in respective regions partitioned by the gate wirings 218 and the source wirings 215. Here, the display device substrate 2 has, in a single pixel, pixel auxiliary capacitances 220a and 220b, which are different from each other.

As shown in FIG. 9, in each pixel of the display device substrate 2, the source of the TFT 213 is connected to the source wiring 215, the gate of TFT 213 is connected to the gate wiring 218, the pixel electrode 216 is connected to the drain of the TFT 213, and the pixel auxiliary capacitances 220a and 220b are both connected to the drain of the TFT 213 and to the auxiliary capacitance wiring 221.

The display device substrate 2 may be a color display device substrate, and the pixel may be a picture element.

Here, the cross-sectional structure is described. As shown in FIGS. 8(a) and 8(c), the display device substrate 2 has, on a main surface of a substrate 210, a multi-layered structure in which a base layer 211, a semiconductor layer 230c, a gate insulating film 212, a first wiring layer 241, a first interlayer insulating film 251 in which a planarizing film is layered over an inorganic insulating film, a second wiring layer 242, a second interlayer insulating film 252 in which an inorganic insulating film 252a is layered over the planarizing film 252b, a third wiring layer 243, and a third interlayer insulating film 253 made of a planarizing film are layered in this order from the side close to the substrate 210. Furthermore, a pixel electrode 216 is disposed on the third interlayer insulating film 253.

TFT 213 is composed of channel regions 231c and 231d, high-concentration impurity regions 233e, 233f, and 233g, a gate insulating film 212, and gate electrodes 219c and 219d. Here, TFT 213 is a top gate (planar) TFT having a single drain structure. Also, TFT 213 has a dual gate structure in which two channel regions 231c and 231d are connected serially, a high-concentration impurity region 233e functions as a source region, and a high-concentration impurity region 233g functions as a drain region. Also, a region of the gate wiring 218 that overlaps the semiconductor layer 230c functions as gate electrodes 219c and 219d. Furthermore, the high-concentration impurity region 233g is formed to reach a region that overlaps the auxiliary capacitance wiring 221.

The gate wiring 218 is a wiring for transmitting scanning signals, and the gate wiring 218 (gate electrodes 219c and 219d) is formed of the first wiring layer 241.

The source wiring 215 is a wiring for transmitting pixel signals (image data), and is formed of the second wiring layer 242. The source wiring 215 and the source region of the TFT 213 (high-concentration impurity region 233e) are connected together via a contact hole running through the gate insulating film 212 and the first interlayer insulating film 251. On the other hand, the drain region of TFT 213 (high-concentration impurity region 233g) is connected to the drain electrode 222 formed of the second wiring layer 242 via a contact hole running through the gate insulating film 212 and the first interlayer insulating film 251.

The upper electrode 226a is formed of the third wiring layer 243, overlapping the auxiliary capacitance wiring 221 and the drain electrode 222. The upper electrode 226a is connected to the drain electrode 222 through a contact hole provided in the second interlayer insulating film 252. The upper electrode 226a is also connected to the pixel electrode 216 through a contact hole provided in the third interlayer insulating film 253.

A lower electrode 227a is formed of the second wiring layer 242 in a region overlapping the auxiliary capacitance wiring 221 formed of the first wiring layer 243. The lower electrode 227a is connected to the auxiliary capacitance wiring 221 via a contact hole provided in the first interlayer insulating film 251. Furthermore, the planarizing film 252b is removed in a region where the lower electrode 227a and the upper electrode 226a overlap. Also, a pixel auxiliary capacitance 220a is formed in a region where the upper electrode 226a and the lower electrode 227a face each other only through the inorganic insulating film 252a (the region enclosed by dashed lines in FIG. 8(a)). Here, the inorganic insulating film 252a also functions as an insulating film (dielectric) of the pixel auxiliary capacitance 220a.

Also, a pixel auxiliary capacitance 220b is formed in a region where the auxiliary capacitance wiring 221 and the high-concentration impurity region 233g are disposed facing each other through the gate insulating film 212 (the region enclosed by dashed-dotted lines in FIG. 8(a)). Here, the auxiliary capacitance wiring 221 also functions as the upper electrode of the pixel auxiliary capacitance 220b, the high-concentration impurity region 233g also functions as the lower electrode of the pixel auxiliary capacitance 220b, and the gate insulating film 212 also functions as an insulating film (dielectric) of the pixel auxiliary capacitance 220b.

A display device substrate 2 of this embodiment can be manufactured in a similar manner as a display device substrate 1 of Embodiment 1.

Accordingly, in the display device substrate 2 of this embodiment, the upper electrode 226a of the pixel auxiliary capacitance 220a is formed of the third wiring layer 243, and the lower electrode 227a of the pixel auxiliary capacitance 220a is formed of the second wiring layer 242. Therefore, a conventional pixel auxiliary capacitance 220b that includes the auxiliary capacitance wiring 221 and the semiconductor layer 230c (high-concentration impurity region 233g) can be disposed to overlap the pixel auxiliary capacitance 220a. Here, because the pixel auxiliary capacitances 220a and 220b, which are different from each other, can be formed in a single pixel, even though the total of the pixel auxiliary capacitances 220a and 220b is increased, the size (area) of respective pixel auxiliary capacitances 220a and 220b can be smaller, compared to the case in which only one pixel auxiliary capacitance is formed in a pixel. That is, both the increase in the pixel auxiliary capacitances 220a and 220b and the aperture ratio improvement can be achieved.

Also, because the pixel auxiliary capacitances 220a and 220b can be formed independent of the constituting elements of the pixel, by a multi-layer wiring technology using the dry process as in Embodiment 1, no additional manufacturing step is necessary to form the pixel auxiliary capacitances 220a and 220b. That is, when applying the present invention to a display device substrate where a multi-layer wiring technology using a dry process is utilized, the manufacturing costs do not increase.

On the other hand, when a multi-layer wiring technology using a wet process is utilized, an inorganic insulating film 252a (passivation film) for preventing damages due to the dry process does not need to be formed. Therefore, an inorganic insulating film 252a has to be formed separately before or after a thick planarizing film 252b is formed. However, because the peripheral circuit and the display section can have a common wiring by forming the upper electrode 226a and the lower electrode 227a of the pixel auxiliary capacitance 220a from the second wiring layer 242 and the third wiring layer 243, and by utilizing a thin inorganic insulating film 252a separately formed as the insulating film of the pixel auxiliary capacitance 220a, the manufacturing cost can partially be reduced. Also in this case, of course, because the pixel auxiliary capacitance 220b can be formed below the pixel auxiliary capacitance 220a, the aperture ratio can be improved.

Also, the lower electrode 227a of the pixel auxiliary capacitance 220a is disposed in such manner as not to extend beyond the upper electrode of the pixel auxiliary capacitance 220b (auxiliary capacitance wiring 221). Therefore, even if only an inorganic insulating film such as a TEOS film deposited by a conventional PECVD method is used as the first interlayer insulating film 251, in which a planarizing film is not provided, no surface unevenness due to the auxiliary capacitance wiring 221 occurs in the first interlayer insulating film 251 in a region where the lower electrode 227a of the pixel auxiliary capacitance 220a is provided. That is, even if the first interlayer insulating film 251 is formed of a conventional inorganic interlayer insulating film, insulation breakdowns across the pixel auxiliary capacitance 220a that can be caused by the surface unevenness due to the auxiliary capacitance wiring 221 can effectively be suppressed.

Below, modification examples of this embodiment is described.

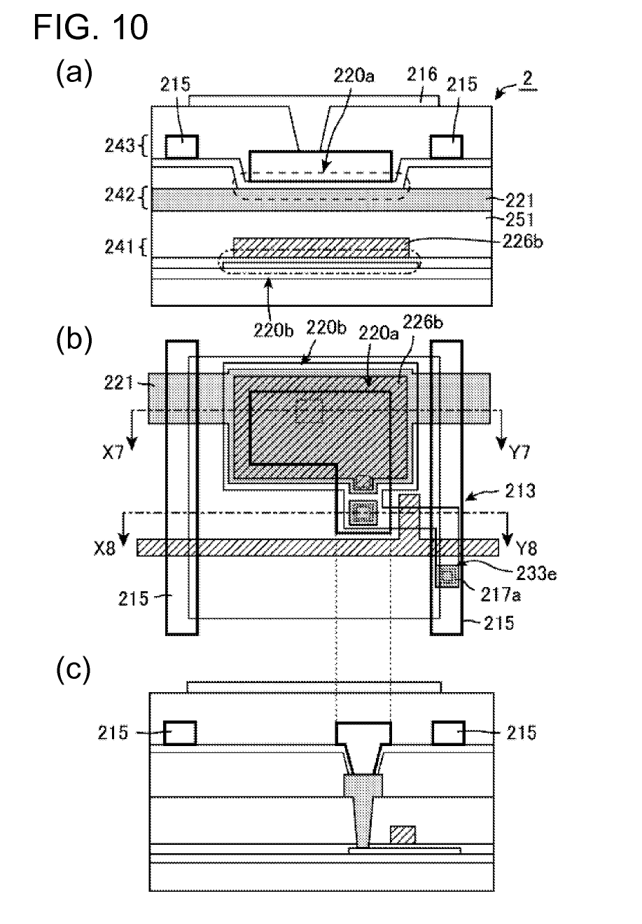

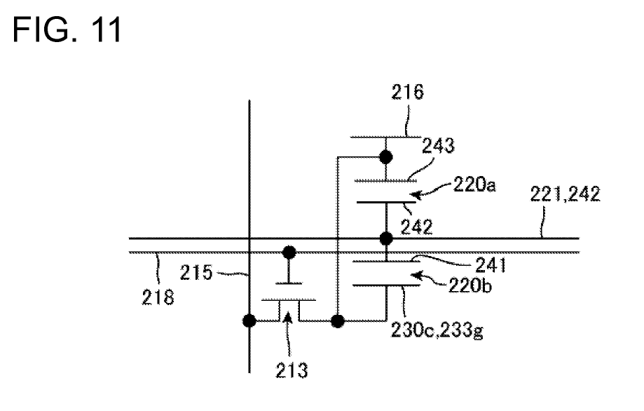

FIG. 10 is a schematic view illustrating the pixel configuration of Modification Example 1 of the display device substrate of Embodiment 2. FIG. 10(b) is a plan view, FIG. 10(a) is a cross-sectional view taken along the line X7-Y7 of FIG. 10(b), and FIG. 10(c) is a cross-sectional view taken along the line X8-Y8 of FIG. 10(b). FIG. 11 is a circuit diagram explaining the pixel circuit in Modification Example 1 of the display device substrate of Embodiment 2. Since Modification Examples 1 to 4 described below are different from the embodiment described above only with respect to the pixel structure, illustration and description of the peripheral circuit is omitted.

As shown in FIGS. 10 and 11, in the display device substrate 2, the source wiring 215 may be formed of the third wiring layer 243, and the auxiliary capacitance wiring 221 may be formed of the second wiring layer 242. In this case, auxiliary capacitance wiring 221 also functions as the lower electrode of the pixel auxiliary capacitance 220a (the region enclosed by dashed lines in FIG. 10(a)). The upper electrode 226b of the pixel auxiliary capacitance 220b (the region enclosed by dashed-dotted lines in FIG. 10(a)) is formed of the first wiring layer 241, and is connected to the auxiliary capacitance wiring 221 through a contact hole provided in the first interlayer insulating film 251. Furthermore, the source wiring 215 is connected to the source region of TFT 213 (high-concentration impurity region 233e) through the connecting section 217a formed of the second wiring layer 242.

Because the pixel auxiliary capacitance 220b can be formed below the pixel auxiliary capacitance 220a also in this modification example, both the increase in the pixel auxiliary capacitances 220a and 220b and the aperture ratio improvement can be achieved. Also, since this modification example can be manufactured in a production process similar to that for Embodiment 1, manufacturing costs can be curbed. Furthermore, in this modification example, although the auxiliary capacitance wiring 221 crosses over the upper electrode 226b of the pixel auxiliary capacitance 220b, because normally the first interlayer insulating film 251 has an enough thickness of at least 400 nm, occurrence of insulation breakdowns across the pixel auxiliary capacitance 220a can sufficiently be suppressed.

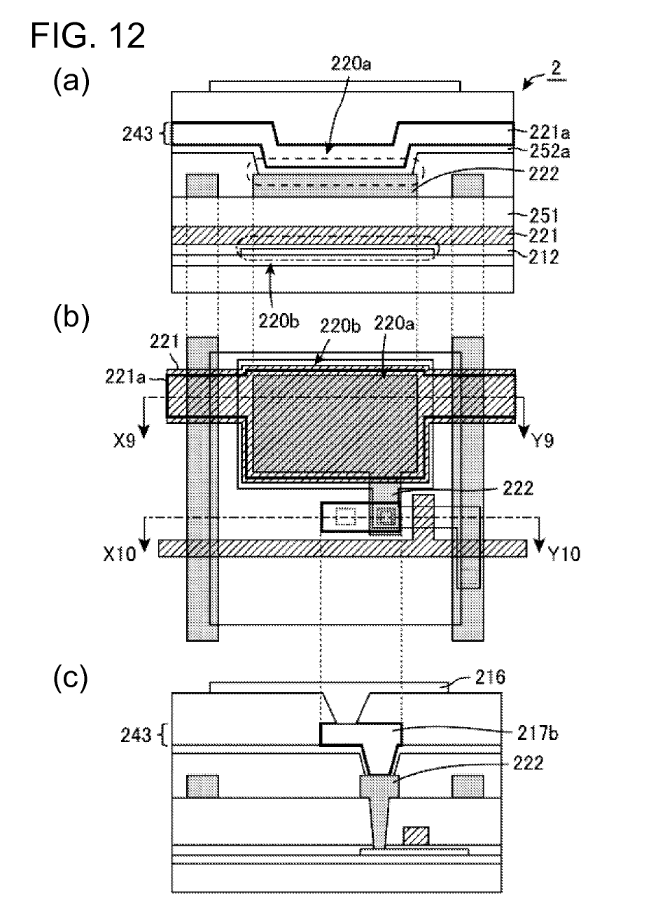

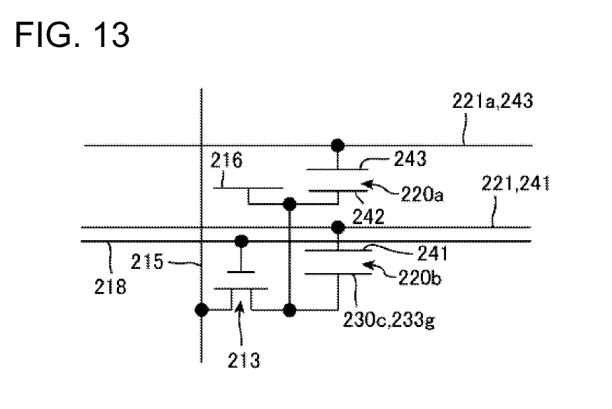

FIG. 12 is a schematic view illustrating the pixel configuration in Modification Example 2 of the display device substrate of Embodiment 2. FIG. 12(b) is a plan view, FIG. 12 (a) is a cross-sectional view taken along the line X9-Y9 of FIG. 12(b), and FIG. 12(c) is a cross-sectional view taken along the line X10-Y10 of FIG. 12(b). FIG. 13 is a circuit diagram explaining the pixel circuit in Modification Example 2 of the display device substrate of Embodiment 2.

As shown in FIGS. 12 and 13, in the display device substrate 2, the auxiliary capacitance wiring 221a, whose electrical potential system is different from that of the auxiliary capacitance wiring 221, may be formed of the third wiring layer 243. In this case, the auxiliary capacitance wiring 221a also functions as the upper electrode of the pixel auxiliary capacitance 220a (the region enclosed by dashed lines in FIG. 12(a)). The drain electrode 222 is formed to extend to the region that overlaps the auxiliary capacitance wiring 221a, and functions as the lower electrode of the pixel auxiliary capacitance 220a also. The drain electrode 222 (the lower electrode of the pixel auxiliary capacitance 220a) is not connected to the auxiliary capacitance wiring 221 of the pixel auxiliary capacitance 220b (the region enclosed by dashed-dotted lines in FIG. 12(a)). Also, the pixel electrode 216 is connected to the drain electrode 222 via the connecting section 217b formed of the third wiring layer 243. The pixel electrode 216 and the connecting section 217b are connected together via a contact hole provided in the third interlayer insulating film 253, and the connecting section 217b and the drain electrode 222 are connected together via a contact hole provided in the second interlayer insulating film 252.

In this modification example as well, because the pixel auxiliary capacitance 220b can be formed below the pixel auxiliary capacitance 220a, both the increase in the pixel auxiliary capacitances 220a and 220b and the aperture ratio improvement can be achieved. Also, since this modification example can be manufactured in a production process similar to that for Embodiment 1, the production cost can be curbed. Furthermore, because the lower electrode of the pixel auxiliary capacitance 220a (drain electrode 222) is disposed over the upper electrode of the pixel auxiliary capacitance 220b (auxiliary capacitance wiring 221), even if the first interlayer insulating film 251 is formed of a conventional inorganic interlayer insulating film, occurrence of insulation breakdowns across the pixel auxiliary capacitance 220a caused by the surface unevenness due to the auxiliary capacitance wiring 221 can effectively be suppressed.

Also, because the pixel auxiliary capacitances 220a and 220b, which belong to two separate systems that include the auxiliary capacitance wiring 221 and auxiliary capacitance wiring 221a respectively, are formed, different voltages can be applied to the pixel auxiliary capacitance 220a and the pixel auxiliary capacitance 220b. For example, if the insulating film of the pixel auxiliary capacitance 220a (inorganic insulating film 252a) and the insulating film of the pixel auxiliary capacitance 220b (gate insulating film 212) have different insulation breakdown voltages, the voltages applied to the capacitances can respectively be optimized according to their breakdown voltages to prevent defects such as insulation breakdown from occurring.

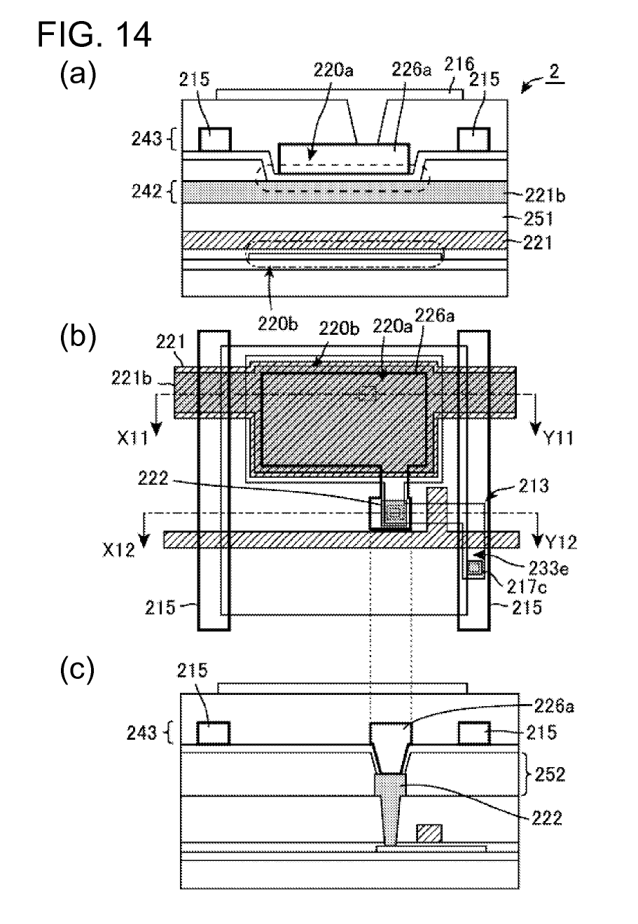

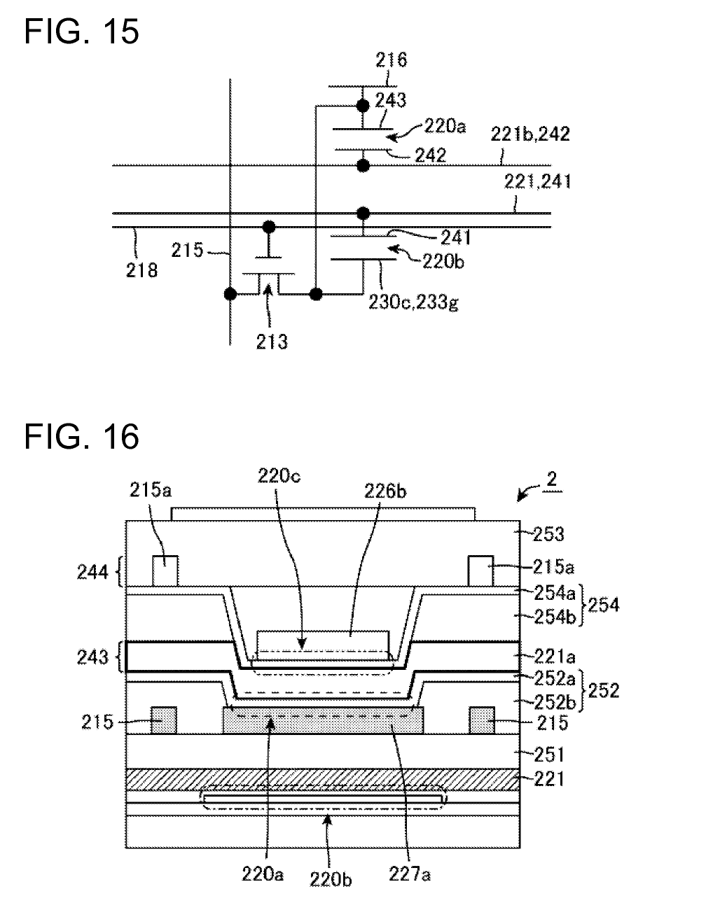

FIG. 14 is a schematic view illustrating the pixel configuration in Modification Example 3 of the display device substrate of Embodiment 2. FIG. 14 (b) is the plan view, FIG. 14 (a) is a cross-sectional view taken along the line X11-Y11 of FIG. 14 (b), and FIG. 14 (c) is a cross-sectional view taken along the line X12-Y12 of FIG. 14 (b). FIG. 15 is a circuit diagram explaining the pixel circuit in Modification Example 3 of the display device substrate of Embodiment 2.

As shown in FIGS. 14 and 15, in the display device substrate 2, the source wiring 215 may be formed of the third wiring layer 243, and auxiliary capacitance wiring 221b, which belongs to a different electrical potential system than the auxiliary capacitance wiring 221, may be formed of the second wiring layer 242. In this case, the auxiliary capacitance wiring 221b also functions as the lower electrode of the pixel auxiliary capacitance 220a (the region enclosed by dashed lines in FIG. 14(a)). Also, the upper electrode 226a of the pixel auxiliary capacitance 220a is connected to the drain electrode 222 via a contact hole provided in the second interlayer insulating film 252. Here, the auxiliary capacitance wiring 221b (the lower electrode of the pixel auxiliary capacitance 220a) is not connected to the auxiliary capacitance wiring 221 of the pixel auxiliary capacitance 220b (the region enclosed by dashed-dotted lines in FIG. 14(a)). The source wiring 215 is connected to the source region of TFT 213 (high-concentration impurity region 233e) through a connecting section 217c formed of the second wiring layer 242.

In this modification example as well, because the pixel auxiliary capacitance 220b can be formed below the pixel auxiliary capacitance 220a, both the increase in pixel auxiliary capacitances 220a and 220b and the aperture ratio improvement can be achieved. Also, because this modification example can be manufactured in a production process similar to that for Embodiment 1, the manufacturing costs can be curbed. Furthermore, since the lower electrode of the pixel auxiliary capacitance 220a (auxiliary capacitance wiring 221b) is disposed over the upper electrode of the pixel auxiliary capacitance 220b (auxiliary capacitance wiring 221), even if the first interlayer insulating film 251 is formed of a conventional inorganic interlayer insulating film, insulation breakdowns that can be caused across the pixel auxiliary capacitance 220a by the surface unevenness due to the auxiliary capacitance wiring 221 can effectively be suppressed.

Also, because the pixel auxiliary capacitances 220a and 220b, which belong to two separate systems that include the auxiliary capacitance wiring 221 and the auxiliary capacitance wiring 221b respectively, are formed, occurrences of defects such as insulation breakdowns can be suppressed in a manner similar to Modification Example 2.

Furthermore, the auxiliary capacitance wiring 221b functions as the lower electrode of the pixel auxiliary capacitance 220a, and the upper electrode 226a of the pixel auxiliary capacitance 220a is connected to the drain electrode 222. Therefore, the contact hole for connecting the pixel electrode 216 to the third wiring layer 243, which is located in a lower layer, can be provided over the upper electrode 226a of the pixel auxiliary capacitance 220a. As a result, aperture ratio can be improved more than Modification Example 2. More specifically, as it is apparent by comparing FIGS. 12(c) and 14(c), the portion of third wiring layer 243 (pad) that is connected to the drain electrode 222 can be made small.

FIG. 16 is a cross-sectional view schematically showing the pixel configuration in Modification Example 4 of the display device substrate of Embodiment 2. FIG. 16 corresponds to a cross-sectional view taken along the line X9-Y9 of FIG. 12(b).

In this modification example, as shown in FIG. 16, an auxiliary capacitance wiring 221a, which belongs to a different electrical potential system from the auxiliary capacitance wiring 221, may be formed of the third wiring layer 243 similarly to Modification Example 2. Also, on the third wiring layer 243, a fourth interlayer insulating film 254 in which an inorganic insulating film 254a is disposed over the planarizing film 254b, and a fourth wiring layer 244 may be formed in this order. Furthermore, an upper electrode 226b may be formed of the fourth wiring layer 244 in a region overlapping the auxiliary capacitance wiring 221a, and a source wiring 215a may be formed of the fourth wiring layer 244 in a region overlapping the source wiring 215. In this case, the auxiliary capacitance wiring 221a also functions as the upper electrode of the pixel auxiliary capacitance 220a (the region enclosed by dashed lines in FIG. 16(a)). Also, the planarizing film 254b is removed in a region where the auxiliary capacitance wiring 221a and the upper electrode 226b overlap, and a pixel auxiliary capacitance 220c is formed in a region where the upper electrode 226b and the auxiliary capacitance wiring 221a are disposed facing each other only through an inorganic insulating film 254a (the region enclosed by dashed-two dotted lines of FIG. 16). Here, the auxiliary capacitance wiring 221a also functions as the lower electrode of the pixel auxiliary capacitance 220c, and the inorganic insulating film 254a also functions as the insulating film (dielectric) of the pixel auxiliary capacitance 220c. The source wiring 215 and the source wiring 215a are connected together via a contact hole running through the second interlayer insulating film 252 and the fourth interlayer insulating film 254.

A fourth interlayer insulating film 254 and a fourth wiring layer 244 can be formed in a manner similar to the third interlayer insulating film 253 and the third wiring layer 243, respectively.

In this modification example, a pixel auxiliary capacitance 220b can be formed below the pixel auxiliary capacitance 220a, and a pixel auxiliary capacitance 220c can be formed above the pixel auxiliary capacitance 220a. Here, because pixel auxiliary capacitances 220a, 220b, and 220c, which are different from one another, can be disposed in one pixel, compared to the case where only the pixel auxiliary capacitances 220a and 220b are disposed, the aperture ratio can be improved. Also, because two layers of source wirings 215 and 215a are formed, each of the source wirings 215 and 215a can be narrower, and as a result, the aperture ratio can further be improved.

Furthermore, this modification example can be manufactured in a production process similar to Embodiment 1, the production costs can be curbed. Also, because the lower electrode 227a of the pixel auxiliary capacitance 220a is disposed over the upper electrode of the pixel auxiliary capacitance 220b (auxiliary capacitance wiring 221), even if the formation process of the first interlayer insulating film 251 is simplified, insulation breakdowns across the pixel auxiliary capacitance 220a, which can be caused by the surface unevenness due to the auxiliary capacitance wiring 221, can effectively be suppressed from occurring.

Because the pixel auxiliary capacitances 220a and 220c, and the pixel auxiliary capacitance 220b, which belong to two separate systems including the auxiliary capacitance wiring 221 and auxiliary capacitance wiring 221a respectively, are formed, occurrences of defects such as insulation breakdowns can be suppressed in a manner similar to Modification Example 2.

### Embodiment 3

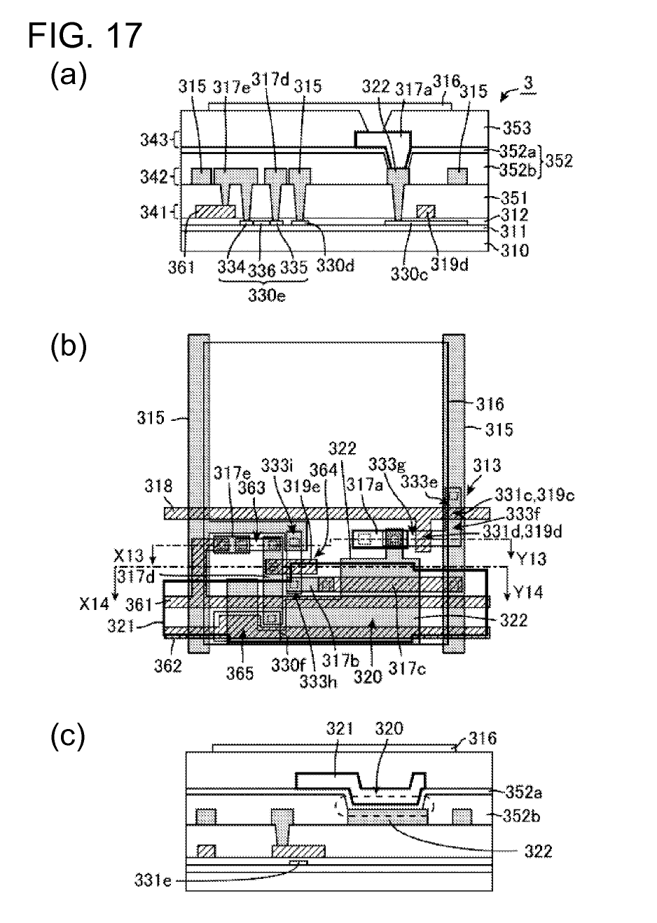

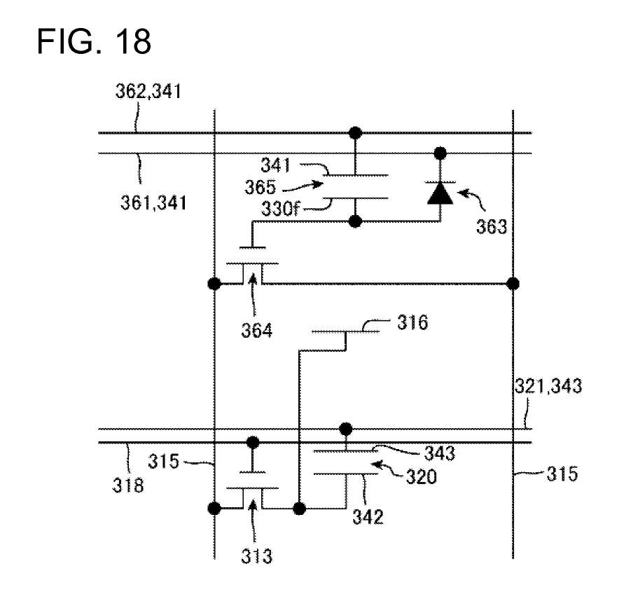

FIG. 17 is a schematic view illustrating the pixel configuration in a display device substrate of Embodiment 3. FIG. 17(b) is a plan view, FIG. 17(a) is a cross-sectional view taken along the line X13-Y13 of FIG. 17(b), and FIG. 17(c) is a cross-sectional view taken along the line X14-Y14 of FIG. 17(b). FIG. 18 is a circuit diagram explaining the pixel circuit in the display device substrate of Embodiment 3. Since this embodiment is different from Embodiment 1 only with respect to the pixel structure, illustration and description of the entire configuration and the peripheral circuit is omitted, and the description below is focused mainly on the display section.

As shown in FIG. 17(b), a display device substrate 3 of Embodiment 3 includes, on a main surface of a substrate 310: a plurality of gate wirings 318, which are in parallel with each other; a plurality of storage capacitance wirings 321, which are disposed in parallel with respective gate wirings 318; a plurality of source wirings 315, which are in parallel with each other and perpendicular to the respective gate wirings 318; a pixel switching TFT 313 provided near the intersection of the gate wiring 318 and the source wiring 315 of each pixel; a plurality of pixel auxiliary capacitances 320 provided in a region of each pixel that overlaps respective auxiliary capacitance wiring 321; a plurality of pixel electrodes 316 provided in respective regions partitioned by the gate wirings 318 and the source wirings 315; a plurality of reset signal wirings 361 and column selection signal wiring 362 provided in parallel with the respective gate wirings 318 and overlapping one another below the respective storage capacitance wirings 321; a PIN diode 363 that functions as a photodiode; an optical sensor TFT 364; and an optical sensor capacitance 365.

As shown in FIG. 18, in each of the pixels of the display device substrate 3, the source of TFT 313 is connected to the source wiring 315, the gate of TFT 313 is connected to the gate wiring 318, the pixel electrode 316 is connected to the drain of TFT 313, the pixel auxiliary capacitance 220 is connected to the drain of TFT 313 and to the auxiliary capacitance wiring 321, the source or drain of TFT 364 (the region that functions as the source or the drain) is connected to the respectively adjacent source wiring 315, the capacitance 365 is connected to the gate of TFT 364 and to the column selection wiring 362, the anode of PIN diode 363 is connected to the gate of TFT 364, and the cathode of PIN diode 363 is connected to the reset signal wiring 361.

The display device substrate 1 may be a color display device substrate, and the aforementioned pixel may be a picture element.

Here, the cross-sectional structure is described. As shown in FIGS. 17(a) and 17(c), the display device substrate 3 has a multi-layered structure in which, on a main surface of the substrate 310, a base layer 311, semiconductor layers 330c, 330d, 330e, and 330f, a gate insulating film 312, a first wiring layer 341, a first interlayer insulating film 351 in which a planarizing film is layered over an inorganic insulating film, a second wiring layer 342, a second interlayer insulating film 352 in which an inorganic insulating film 352a is layered over a planarizing film 352b, a third wiring layer 343, and a third interlayer insulating film 353 made of a planarizing film are layered in this order from the side close to the substrate 310, and furthermore, a pixel electrode 316 is provided on the third interlayer insulating film 353.

TFT 313 is composed of channel regions 331c and 331d, high-concentration impurity regions 333e, 333f, and 333g, a gate insulating film 312, and a gate electrodes 319c and 319d. Here, TFT 313 is a top gate (planar) TFT having a single drain structure. Also, TFT 313 has a dual gate structure in which two channel regions 331c and 331d are serially connected, the high-concentration impurity region 333e functions as a source region, and the high-concentration impurity region 333g functions as a drain region. The region of the gate wiring 318 that overlaps the semiconductor layer 330c functions as the gate electrodes 319c and 319d.

A gate wiring 318 is a wiring for scan signal transmission. The gate wiring 318 (gate electrodes 319c and 319d) is formed of the first wiring layer 341.

The source wiring 315 is a wiring for transmitting the pixel signals (image data), and is formed of the second wiring layer 342. Also, the source wiring 315 and the source region of TFT 313 (the high-concentration impurity region 333e) are connected to each other via a contact hole running through the gate insulating film 312 and the first interlayer insulating film 351. On the other hand, the drain region of TFT 313 (high-concentration impurity region 333g) is connected to the drain electrode 322 formed of the second wiring layer 342 via a contact hole running through the gate insulating film 212 and the first interlayer insulating film 351.

Also, the drain electrode 322 is connected to the pixel electrode 316 via a connecting section 317a formed of the third wiring layer 343. The pixel electrode 316 and the connecting section 317a are connected to each other via a contact hole provided in the third interlayer insulating film 353. The drain electrode 322 and the connecting section 317a are connected to each other via a contact hole provided in the second interlayer insulating film 352. Furthermore, the drain electrode 322 is formed to extend to the region that overlaps the auxiliary capacitance wiring 321.

The auxiliary capacitance wiring 321 is formed of the third wiring layer 343, and the planarizing film 352b is removed in the region where the auxiliary capacitance wiring 321 and the drain electrode 322 overlap. A pixel auxiliary capacitance 320 is formed in a region where the drain electrode 322 and the auxiliary capacitance wiring 321 are disposed to face each other only through the inorganic insulating film 352a (the region enclosed by dashed lines in FIG. 17(c)). Here, the drain electrode 322 also functions as the lower electrode of the pixel auxiliary capacitance 320, the auxiliary capacitance wiring 321 also functions as the upper electrode of the pixel auxiliary capacitance 320, and the inorganic insulating film 352a also functions as an insulating film (dielectric substance) of the pixel auxiliary capacitance 320.

TFT 364 is composed of a channel region 331e, high-concentration impurity regions 333h and 333i, a gate insulating film 312, and a gate electrode 319e formed of the first wiring layer 341. Here, TFT 364 is a top gate (planar) TFT having a single drain structure. The high-concentration impurity regions 333h and 333i function as the source or the drain region, respectively.

Furthermore, the high-concentration impurity regions 333h and 333i are respectively connected to the adjacent source wirings 315. The high-concentration impurity region 333h is connected to the source wiring 315 through the connecting section 317b formed of the second wiring layer 342 and the connecting section 317c formed of the first wiring layer 341. The high-concentration impurity region 333h and the connecting section 317b are connected to each other through a contact hole running through the gate insulating film 312 and the first interlayer insulating film 351. The connecting section 317b and the connecting section 317c are connected to each other through a contact hole running through the first interlayer insulating film 351. Furthermore, the connecting section 317c and the source wiring 315 are connected to each other through a contact hole running through the first interlayer insulating film 351. The high-concentration impurity region 333i and the source wiring 315 are connected to each other through a contact hole running through the gate insulating film 312 and the first interlayer insulating film 351.

PIN diode 363 is composed of an N-type impurity region 334 to which an N-type impurity was introduced in high concentration, a P-type impurity region 335 to which a P-type impurity was introduced in high concentration, and an I-type region 336, which is an intrinsic semiconductor or to which an impurity was introduced in small amounts. The P-type impurity region 335 functions as the anode, and the N-type impurity region 334 functions as the cathode. The anode of PIN diode 363 (P-type impurity region 335) is connected to the gate electrode 319e of TFT 364 through the connecting section 317d formed of the second wiring layer 342. The anode of PIN diode 363 (P-type impurity region 335) and the connecting section 317d are connected to each other via a contact hole running through the gate insulating film 312 and the first interlayer insulating film 351. The gate electrode 319e and the connecting section 317d are connected to each other via a contact hole running through the first interlayer insulating film 351. Since the PIN diode 363 is a light-receiving element, it is provided in a region where the light is not blocked by wiring layers such as the first wiring layer 341, the second wiring layer 342, or the third wiring layer 343.

The reset signal wiring 361 is a wiring for transmitting the reset signals, and is formed of the first wiring layer 341. The reset signal wiring 361 is connected to the cathode of the PIN diode 363 (N-type impurity region 334) through a connecting section 317e formed of the second wiring layer 342. The reset signal wiring 361 and the connecting section 317e are connected to each other via a contact hole running through the first interlayer insulating film 351. Also, the cathode of the PIN diode 363 (N-type impurity region 334) and the connecting section 317e are connected to each other via a contact hole running through the gate insulating film 312 and the first interlayer insulating film 351.

The semiconductor layer 330f is a high-concentration impurity region, and is formed to overlap the column selection wiring 362. Also, the semiconductor layer 330f is connected to the gate electrode 319e of TFT 364 through the connecting section 317d that intersects with the reset signal wiring 361. The semiconductor layer 330f and the connecting section 317d are connected to each other via a contact hole running through the gate insulating film 312 and the first interlayer insulating film 351.

The column selection wiring 362 is a wiring for transmitting the column selection signals, and is formed of the first wiring layer 341. A capacitance 365 is formed in a region where column selection wiring 362 and the semiconductor layer 330f are disposed to face each other via the gate insulating film 312. Here, semiconductor layer 330f functions as the lower electrode of the capacitance 365, the column selection wiring 362 also functions as the upper electrode of the capacitance 365, and the gate insulating film 312 also functions as the insulating film (dielectric) of the capacitance 365.

Because the connecting section 317d and the connecting section 317e are formed of the second wiring layer 342, which is the same as the lower electrode of the pixel auxiliary capacitance 320 (drain electrode 322), the contact hole connecting the connecting section 317e and the reset signal wiring 361 together, the contact hole connecting the connecting section 317e and the cathode of PIN diode 363, and the connecting section 317d that intersects with the reset signal wiring 361 are disposed outside the pixel auxiliary capacitance 320.

The display device substrate 3 according to this embodiment can be manufactured in a manner similar to the display device substrate 1 of Embodiment 1.

In the display device substrate 3 of this embodiment described above, the upper electrode of the pixel auxiliary capacitance 320 (auxiliary capacitance wiring 321) is formed of the third wiring layer 343, and the lower electrode of the pixel auxiliary capacitance 320 (drain electrode 322) is formed of the second wiring layer 342. Therefore, constituent members of the optical sensor circuit, such as the reset signal wiring 361, column selection wiring 362, and the capacitance 365 can be disposed below the second wiring layer 342, overlapping the pixel auxiliary capacitance 320. As a result, even if the pixel auxiliary capacitance 320 is made larger, members such as the reset signal wiring 361, the column selection wiring 362, and the capacitance 365 can contribute to a higher aperture ratio. That is, both the increase in pixel auxiliary capacitance 320 and the aperture ratio improvement can be achieved.

Here, similarly to the case of Embodiment 1, because the pixel auxiliary capacitance 320 can be formed by utilizing a multi-layer wiring technology using a dry process, independent of the constituting elements of pixels, no additional manufacturing step is necessary to form the pixel auxiliary capacitance 320. That is, when applying the present invention to a display device substrate in which a multi-layer wiring technology using a dry process is utilized, the manufacturing costs do not increase.

On the other hand, when a multi-layer wiring technology using a wet process is utilized, an inorganic insulating film 352a (passivation film), which is for preventing any damages due to the dry process from occurring, does not need to be formed. Therefore, an inorganic insulating film 352a has to be formed separately before or after a thick planarizing film 352b is formed. However, because the peripheral circuit and the display section can have a common wiring by forming the upper electrode (auxiliary capacitance wiring 321) and the lower electrode (drain electrode 322) of the pixel auxiliary capacitance 320 from the second wiring layer 342 and the third wiring layer 343, and by utilizing a thin inorganic insulating film 352a separately formed as the insulating film of the pixel auxiliary capacitance 320, the manufacturing costs can be partially reduced. Also in this case, of course, because members such as the reset signal wiring 361, the column selection wiring 362, and the capacitance 365 can be formed below the pixel auxiliary capacitance 320, the aperture ratio can be improved.

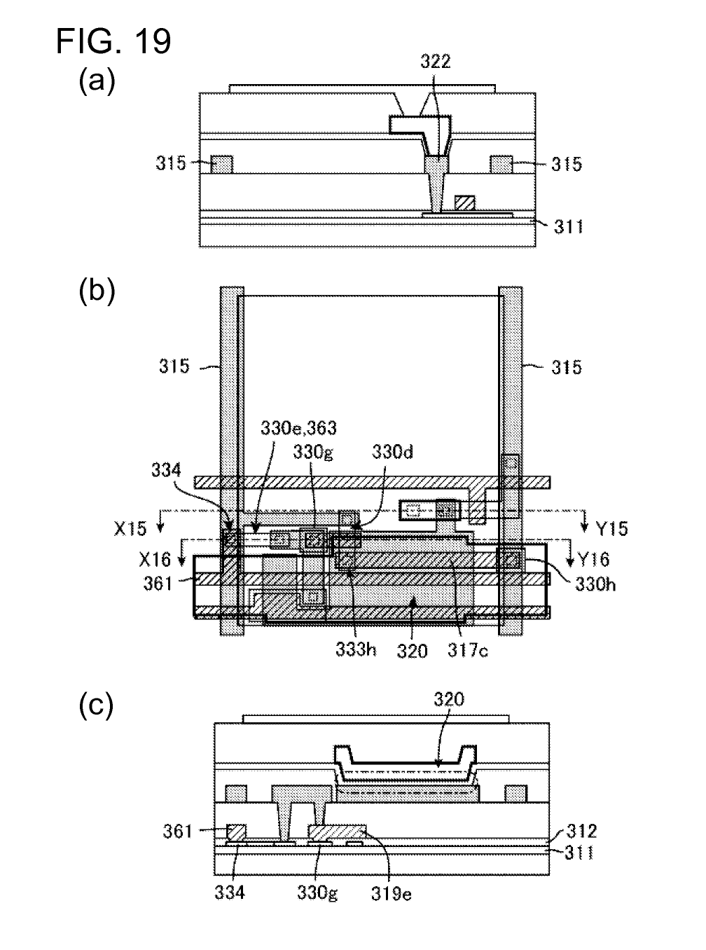

Below, a modification example of this embodiment of the present invention is described. FIG. 19 is a schematic view illustrating the pixel configuration in a modification example of the display device substrate of Embodiment 3. FIG. 19(b) is a plan view, FIG. 19(a) is a cross-sectional view taken along the line X15-Y15 of FIG. 19(b), and FIG. 19(c) is a cross-sectional view taken along the line X16-Y16 of FIG. 19(b). Since this modification example is different from the embodiment described above only with respect to the pixel configuration, illustration and description of the peripheral circuit are omitted.

Conventionally, there was no manufacturing step in which the first wiring layer 341 and the semiconductor layer are connected to each other directly. Conventionally, the second wiring layer 342 and the semiconductor layer, and the second wiring layer 342 and the first wiring layer 341 are connected to each other simultaneously.

In contrast, as shown in FIG. 19, in the display device substrate 3, semiconductor layers such as the semiconductor layers 330d and 330e and the first wiring layer 341 may be connected directly. In this case, the high-concentration impurity region 333h of the semiconductor layer 330d is connected to the source wiring 315 only through the connecting section 317c formed of the first wiring layer 341. Also, the cathode of the PIN diode 363 (N-type impurity region 334) is connected directly to the reset signal wiring 361 via a contact hole provided in the gate insulating film 312.

Consequently, a routing wiring formed of the first wiring layer 341 can be more utilized, and therefore, compared to the embodiments described above, more circuits (wiring) can be disposed below the pixel auxiliary capacitance 320. That is, further aperture ratio improvement can be achieved while increasing the pixel auxiliary capacitance 320.

Because this modification example can be manufactured in a production process similar to Embodiment 1, production costs can also be curbed.

Furthermore, in this modification example, in the region where the first wiring layer 341 and the second wiring layer 342 are connected to each other, island-shaped semiconductor layers 330g and 330h are provided as a base (cushion). The semiconductor layer 330g is connected only to the gate electrode 319e, and is electrically equivalent to the gate electrode 319e. The semiconductor layer 330h is connected only to the connecting section 317c, and is electrically equivalent to the connecting section 317c. Therefore, the manufacturing step to form a contact hole for connecting the first wiring layer 341 and the semiconductor layers 330d and 330e together can be conducted without adding any mask. More specifically, a mask for forming a contact hole for connecting the second wiring layer 342 to the first wiring layer 341 and to the semiconductor layer can be utilized as a mask for forming a contact hole for connecting the first wiring layer 341 to the semiconductor layers 330d and 330e and for preventing the base layer 311 from being etched unintentionally. That is, defects caused by the etching of the base layer 311, such as impurity diffusion from the substrate 310 and the breakage in the first wiring layer 341, can be prevented from occurring, and the production costs can be curbed even further.

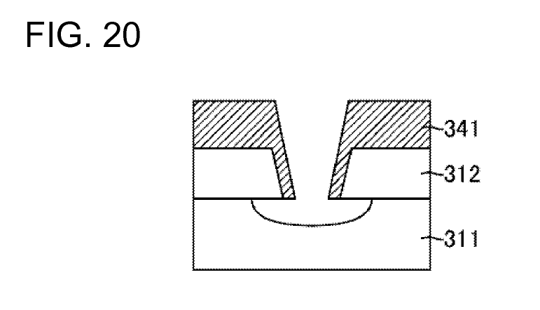

More specifically, upon formation of the contact hole for connecting the first wiring layer 341 to the semiconductor layers 330d and 330e, as shown in FIG. 20, there is a chance that the base layer 311 in the region for connecting the first wiring layer 341 and the second wiring layer 342 is also etched away. However, in this region, semiconductor layers 330g and 330h are provided, and the semiconductor layers 330g and 330h function as etch stoppers against the hydrofluoric acid etching or the like. As a result, the base layer 311 is prevented from being etched away.

In conclusion, in a display device substrate according to Embodiments 1 to 3, a high aperture ratio can be achieved while production costs are suppressed.

Each of the embodiments may be combined where appropriate. For example, members such as the gate wiring, pixel switching TFT, reset signal wiring, column selection wiring, and optical sensor capacitances can be disposed below the pixel auxiliary capacitance. Furthermore, a pixel memory and a light-shielding film may be formed above or below the pixel auxiliary capacitance of respective embodiments.

The liquid crystal mode of the liquid crystal display panel to which a display device substrate of the present invention is applied is not particularly limited, and it may be TN (Twisted Nematic) mode, IPS (In Plane Switching) mode, or VATN (Vertical Alignment Twisted Nematic) mode, for example. Also, a liquid crystal display panel to which a display device substrate of the present invention is applied may be a multi-domain type. A liquid crystal display panel to which a display device substrate of the present invention is applied may be a color display or a black and white display. Furthermore, a liquid crystal display panel to which a display device substrate of the present invention is applied may be a transmissive type, reflective type, or semi-transmissive type (reflective transmissive type).

Further, a display device substrate of the present invention may be applied to an organic EL panel. In that case, an active matrix type organic EL panel in which a pixel auxiliary capacitance is formed is suitable as an organic EL panel to which a display device substrate of the present invention can be applied. On the other hand, an organic EL panel to which a display device substrate of the present invention is applied may be a top-emission type or bottom-emission type. Also, an organic EL panel to which a display device substrate of the present invention is applied may contain a low-molecular light-emitting material or contain a high-molecular light-emitting material. Furthermore, the color display system of an organic EL panel to which a display device substrate of the present invention is applied may be a tri-color system, color conversion system, or color filter system.

### Comparison Example 1

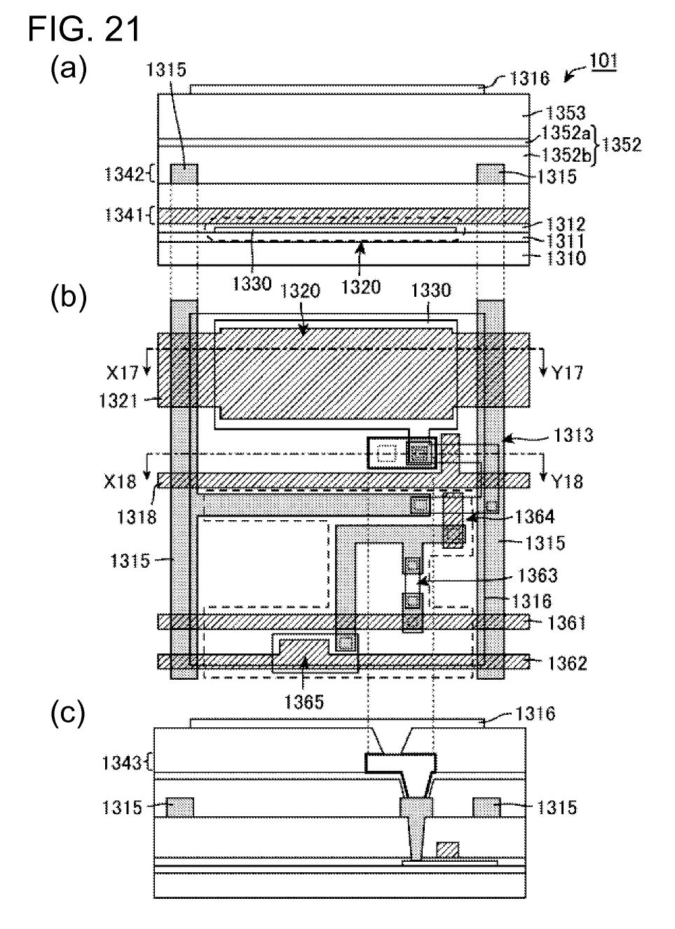

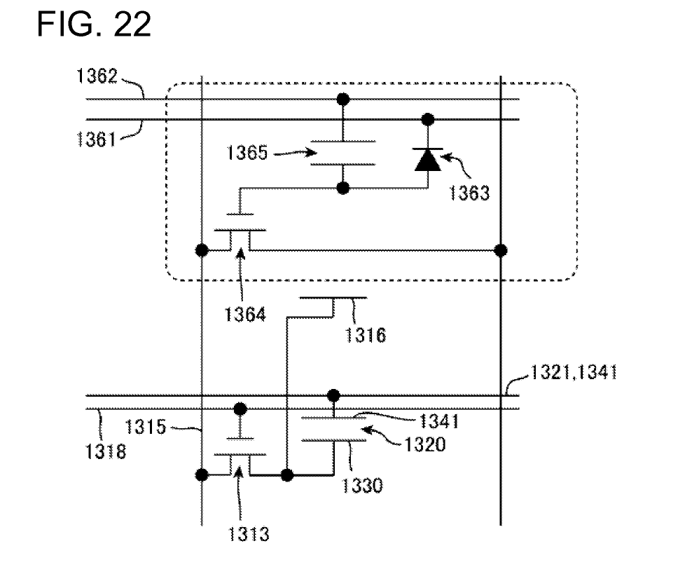

FIG. 21 is a schematic view illustrating the pixel configuration of a display device substrate of Comparison Example 1. FIG. 21(b) is a plan view, FIG. 21(a) is a cross-sectional view taken along the line X17-Y17 of FIG. 21 (b), and FIG. 21(c) is a cross-sectional view taken along the line X18-Y18 of FIG. 21(b). FIG. 22 is a circuit diagram explaining the pixel circuit of a display device substrate of Comparison Example 1.

As shown in FIG. 21(b), in a display device substrate 101 of Comparison Example 1, a substrate 1310 has on one of its main surfaces: a plurality of gate wirings 1318, which are arranged in parallel with each other; a plurality of storage capacitance wirings 1321, which are disposed in parallel with respective gate wirings 1318; a plurality of source wirings 1315, which are parallel with each other and perpendicular to respective gate wirings 1318; a pixel switching TFT 1313, which is provided near the intersection of the gate wiring 1318 and the source wiring 1315 in each pixel; a plurality of pixel auxiliary capacitance 1320 provided in the regions of respective pixels that overlap the respective auxiliary capacitance wirings 1321; a plurality of pixel electrodes 1316 provided in respective regions partitioned by the gate wirings 1318 and the source wirings 1315; a plurality of reset signal wirings 1361 and column selection wirings 1362, which are provided in parallel with respective gate wirings 1318; a PIN diode 1363 that functions as a photodiode; an optical sensor TFT 1364; and an optical sensor capacitance 1365.

As shown in FIG. 22, in each pixel of the display device substrate 101, the source of the TFT 1313 is connected to the source wiring 1315, the gate of TFT 1313 is connected to the gate wiring 1318, the pixel electrode 1316 is connected to the drain of TFT 1313, the pixel auxiliary capacitance 1220 is connected to the drain of TFT 1313 and the auxiliary capacitance wiring 1321, the source and drain of TFT 1364 are connected respectively to the adjacent source wirings 1315, the capacitance 1365 is connected to the gate of TFT 1364 and to the column selection wiring 1362, the anode of PIN diode 1363 is connected to the gate of TFT 1364, and the cathode of PIN diode 1363 is connected to the reset signal wiring 1361.

Here, the cross-sectional structure is described. As shown in FIGS. 21(a) and 21(c), the display device substrate 101 has, on a main surface of the substrate 1310, a multi-layered structure in which a base layer 1311, a semiconductor layer, a gate insulating film 1312, a first wiring layer 1341, a first interlayer insulating film 1351 in which a planarizing film is layered over an inorganic insulating film, a second wiring layer 1342, a second interlayer insulating film 1352 in which an inorganic insulating film 1352a is layered over a planarizing film 1352b, a third wiring layer 1343, and a third interlayer insulating film 1353, which is made of a planarizing film, are layered in this order from the side close to the substrate 1310. Furthermore, a pixel electrode 1316 is disposed on the third interlayer insulating film 1353.

In a display device substrate 101 of this comparison example, the lower electrode of the pixel auxiliary capacitance 1320 is formed of the semiconductor layer 1330, and the upper electrode of the pixel auxiliary capacitance 1320 (auxiliary capacitance wiring 1321) is formed of the first wiring layer 1341. Therefore, members such as TFT 1313, gate wiring 1318, reset signal wiring 1361, column selection wiring 1362, and capacitance 1365 cannot be disposed below the pixel auxiliary capacitance 1320, and therefore the aperture ratio is lowered.

The present application claims priority to Patent Application No. 2008-305300 filed in Japan on Nov. 28, 2008 under the Paris Convention and provisions of national law in a designated State. The entire contents of which are hereby incorporated by reference.

### DESCRIPTION OF REFERENCE CHARACTERS

1, 2, 3: display device substrate
11: display section
12: frame region
110, 210, 310: substrate
111, 211, 311: base layer
112, 212, 312: gate insulating film
113, 213, 313: pixel switching transistor
115, 215, 215a, 315: source wiring
116, 216, 316: pixel electrode
117a, 117b, 117c, 117d, 117e, 117f, 217a, 217b, 217c, 317a, 317b, 317c, 317d, 317e: connecting section
118, 218, 318: gate wiring
119a, 119b, 119c, 119d, 219c, 219d, 319c, 319d, 319e: gate electrode
120, 220a, 220b, 220c, 320: pixel auxiliary capacitance
121, 221, 221a, 221b, 321: auxiliary capacitance wiring
122, 222, 322: drain electrode
124: N-channel type thin film transistor (Nch-TFT)
125: P-channel type thin film transistor (Pch-TFT)
126, 226a, 226b: upper electrode
227a: lower electrode
130a, 130b, 130c, 230c, 330c, 330d, 330e, 330f, 330g, 330h: semiconductor layer
131a, 131b, 131c, 131d, 231c, 231d, 331c, 331d, 331e: channel region
133a, 133b, 133c, 133d, 133e, 133f, 133g, 233e, 233f, 233g, 333e, 333f, 333g, 333h, 333i: high-concentration impurity region
334: N-type impurity region
335: P-type impurity region
336: I-type region
141, 241, 341: first wiring layer
142, 242, 342: second wiring layer
143, 243, 343: third wiring layer
244: fourth wiring layer
151, 251, 351: first interlayer insulating film
152, 252, 352: second interlayer insulating film
152a, 252a, 352a: inorganic insulating film
152b, 252b, 352b: planarizing film
153, 253, 353: third interlayer insulating film
254: fourth interlayer insulating film
254a: inorganic insulating film
254b: planarizing film
361: reset signal wiring
362: column selection wiring
363: PIN diode
364: optical sensor TFT
365: optical sensor capacitance
Vₛₛ: low-voltage power supply wiring
V_{dd}: high-voltage power supply wiring
Vᵢₙ: input voltage wiring
Vₒᵤₜ: output voltage wiring

1. A display device substrate comprising a peripheral circuit provided in a frame region, a first pixel auxiliary capacitance, and a thin film transistor,
wherein said first pixel auxiliary capacitance includes an upper electrode and a lower electrode,
wherein said peripheral circuit includes wirings,
wherein said thin film transistor includes a gate electrode, and
wherein said upper electrode and said lower electrode are in a layer disposed above said gate electrode and are formed of same materials as said wirings.

2. The display device substrate according to claim 1, wherein said lower electrode is connected to a conductive layer through a first contact hole provided in an insulating film in a lower layer, outside a region where said first pixel auxiliary capacitance is formed.

3. The display device substrate according to claim 1, wherein said display device substrate has a second pixel auxiliary capacitance below said first pixel auxiliary capacitance.

4. The display device substrate according to claim 3,
wherein said second pixel auxiliary capacitance includes an upper electrode and a lower electrode, and
wherein said lower electrode of said first pixel auxiliary capacitance does not extend beyond the upper electrode of said second pixel auxiliary capacitance when observed in a plan view.

5. The display device substrate according to claim 3, further comprising a first auxiliary capacitance wiring and a second auxiliary capacitance wiring that is different from said first auxiliary capacitance wiring,
wherein said first pixel auxiliary capacitance is connected to said first auxiliary capacitance wiring, and
wherein said second pixel auxiliary capacitance is connected to said second auxiliary capacitance wiring.

6. The display device substrate according to claim 5, further comprising a drain electrode connected to a drain region of said thin film transistor,
wherein said first auxiliary capacitance wiring is connected to the lower electrode of said first pixel auxiliary capacitance, and
wherein the upper electrode of said first pixel auxiliary capacitance is connected to said drain electrode through a second contact hole provided in an insulating film in a lower layer.

7. The display device substrate according to claim 1, further comprising a third pixel auxiliary capacitance above said first pixel auxiliary capacitance,
wherein said third pixel auxiliary capacitance includes the upper electrode of said first pixel auxiliary capacitance as a lower electrode.

8. The display device substrate according to claim 1, further comprising a semiconductor layer, a gate insulating film, and a first wiring, wherein said first wiring is disposed in a layer directly above said gate insulating film, and is connected to said semiconductor layer through a third contact hole provided in said gate insulating film.

9. The display device substrate according to claim 8, further comprising a second wiring and a base semiconductor layer,
wherein said second wiring is disposed in a layer directly above said gate insulating film, and
wherein said base semiconductor layer is connected only to said second wiring through a fourth contact hole provided in said gate insulating film.

10. The display device substrate according to claim 1, further comprising an interlayer insulating film, which is composed of a first planarizing film and a first inorganic insulating film layered in this order from a lower side,
wherein said first pixel auxiliary capacitance includes a dielectric, and
wherein said dielectric is an insulating film that is continuous from said first inorganic insulating film.

11. The display device substrate according to claim 10, wherein said first planarizing film is a photosensitive resin film.

12. The display device substrate according to claim 10, wherein said first planarizing film is wet-etched.

13. The display device substrate according to claim 1, further comprising an interlayer insulating film including a second planarizing film between the lower electrode of said first pixel auxiliary capacitance and said gate electrode.

14. The display device substrate according to claim 13, further comprising at least one of a wiring, an electrode or an element disposed in a layer that is lower than the lower electrode of said first pixel auxiliary capacitance,
wherein the lower electrode of said first pixel auxiliary capacitance extends beyond at least one of said wiring, said electrode, and said element.

15. A display device comprising the display device substrate according to claim 1.
